(19) United States
(12) Patent Application Publication
(10) Pub. No.: US 2026/0334057 A1
(43) Pub. Date: Oct. 22, 2026

(54) DISPLAY PANEL, ELECTRONIC DEVICE INCLUDING THE SAME, AND METHOD OF MANUFACTURING DISPLAY PANEL

(71) Applicant: Samsung Display Co., Ltd., Yongin-si (KR)

(72) Inventor: HAELIN YONG, Yongin-si (KR)

(21) Appl. No.: 19/460,110

(22) Filed: Jan. 26, 2026

(30) Foreign Application Priority Data
Apr. 21, 2025 (KR) 10-2025-0051718

(51) Int. Cl. H10K 59/80; H10K 59/12

(52) U.S. Cl. CPC H10K 59/873; H10K 59/1201

(57) ABSTRACT

Disclosed is display panel including a base substrate including a display area, and a non-display area surrounding the display area in plan view, and including a first non-display area, and a second non-display area surrounding the first non-display area in plan view, a circuit element layer above the base substrate, a light-emitting element layer including a light-emitting element in the display area and above the circuit element layer, a partition wall defining an opening surrounding the display area in plan view, overlapping the first non-display area, and above the circuit element layer, and an encapsulation layer above the light-emitting element layer and including a first inorganic layer inside the opening and not overlapping the second non-display area, an organic layer above the first inorganic layer, inside the opening, and not overlapping the second non-display area, and a second inorganic layer above the organic layer.

### CROSS-REFERENCE TO RELATED APPLICATION

The present application claims priority to, and the benefit of, Korean Patent Application No. 10-2025-0051718, filed on Apr. 21, 2025, in the Korean Intellectual Property Office, the entire disclosure of which is incorporated herein by reference.

### BACKGROUND

Embodiments of the present disclosure described herein relate to a display panel having a reduced area of a non-display area and improved process efficiency, an electronic device including the same, and a method of manufacturing a display panel.

Generally, electronic devices, such as smartphones, digital cameras, laptop computers, navigation systems, and smart televisions, which provide images to a user, include display panels for displaying the images. The display panel generates an image, and provides the generated image to the user through a display screen.

The display panel may include a light-emitting element using an organic light-emitting material or the like. This light-emitting element may be very vulnerable to oxygen and moisture, and various defects may occur when oxygen and moisture penetrate from the outside. Accordingly, an encapsulation layer for protecting the light-emitting element has been developed.

The display panel may include a display area in which an image is implemented, and a non-display area in which an image is not implemented. Recently, development for expanding the display area by reducing an area of the non-display area has been carried out.

### SUMMARY

Embodiments of the present disclosure provide a display panel having a reduced area of a non-display area.

Embodiments of the present disclosure also provide an electronic device including a display panel having a reduced area of a non-display area.

Embodiments of the present disclosure also provide a method of manufacturing a display panel having a reduced area of a non-display area and improved process efficiency.

According to one or more embodiments, a display panel includes a base substrate including a display area, and a non-display area surrounding the display area in plan view, and including a first non-display area, and a second non-display area surrounding the first non-display area in plan view, a circuit element layer above the base substrate, a light-emitting element layer including a light-emitting element in the display area and above the circuit element layer, a partition wall defining an opening surrounding the display area in plan view, overlapping the first non-display area, and above the circuit element layer, and an encapsulation layer above the light-emitting element layer and including a first inorganic layer inside the opening and not overlapping the second non-display area, an organic layer above the first inorganic layer, inside the opening, and not overlapping the second non-display area, and a second inorganic layer above the organic layer.

The partition wall may include an inner side surface corresponding to the opening, and an outer side surface opposite to the inner side surface, wherein the inner side surface and the outer side surface are substantially perpendicular to the base substrate.

The second inorganic layer may be inside the opening and not overlap the second non-display area.

A thickness of the partition wall may be equal to or greater than a thickness of the encapsulation layer.

The first inorganic layer may include a first edge contacting the inner side surface of the partition wall, wherein the organic layer includes a second edge contacting the inner side surface of the partition wall, wherein the second inorganic layer includes a third edge contacting the inner side surface of the partition wall, and wherein the first edge, the second edge, and the third edge are aligned.

The first edge, the second edge, and the third edge may be substantially perpendicular to the base substrate.

The partition wall may be directly on the circuit element layer.

The partition wall may include an upper surface spaced from the circuit element layer and substantially parallel to the base substrate.

The partition wall may be spaced from the light-emitting element layer in plan view.

The partition wall may include a photocurable resin.

According to one or more embodiments, an electronic device includes a window including a transmissive area, and a bezel area surrounding the transmissive area, and a display panel below the window, and including a base substrate including a display area, and a non-display area surrounding the display area in plan view and including a first non-display area and a second non-display area surrounding the first non-display area in plan view, a circuit element layer above the base substrate, a light-emitting element layer including a light-emitting element in the display area and above the circuit element layer, a partition wall defining an opening surrounding the display area, overlapping the first non-display area, and above the circuit element layer, and an encapsulation layer above the light-emitting element layer and including a first inorganic layer inside the opening and not overlapping the second non-display area, an organic layer above the first inorganic layer, inside the opening, and not overlapping the second non-display area, and a second inorganic layer above the organic layer.

The electronic device may further include at least one of a processor, a memory, or a power module.

The electronic device may be a television, a monitor, an external billboard, a personal computer, a laptop computer, a personal digital terminal, a car instrument panel, a center fascia, a navigation system, a room mirror display, a game console, a smartphone, a tablet computer, a smart watch, smart glasses, a head-mounted display, or a camera.

According to one or more embodiments, a method of manufacturing a display panel includes providing a preliminary display panel including a base substrate, a circuit element layer above the base substrate, and light-emitting element layers above the circuit element layer, forming partition walls surrounding the light-emitting element layers in plan view and defining openings overlapping the light-emitting element layers above the preliminary display panel using a mold, and forming encapsulation layers above the light-emitting element layers by forming first inorganic layers inside the openings above the light-emitting element layers, and forming organic layers inside the openings above the first inorganic layers.

The forming of the partition walls may include applying a photocurable resin onto the preliminary display panel, compressing the mold onto the photocurable resin, photocuring the photocurable resin by radiating an ultraviolet ray to the photocurable resin, and removing the mold.

The forming of the first inorganic layers may include depositing an inorganic material inside the openings using a mask defining mask openings corresponding to the openings.

The forming of the encapsulation layers may further include forming second inorganic layers inside the openings above the organic layers.

The forming of the second inorganic layers may include depositing an inorganic material inside the openings using a mask defining mask openings corresponding to the openings.

The partition walls may include inner side surfaces corresponding to the openings and outer side surfaces opposite to the inner side surfaces, wherein the first inorganic layers include first edges respectively contacting the inner side surfaces, wherein the organic layers include second edges respectively contacting the inner side surfaces, wherein the second inorganic layers include third edges respectively contacting the inner side surfaces, and wherein the first edge, the second edge, and the third edge are aligned.

The method may further include forming display panels by cutting the preliminary display panel in which the partition walls and the encapsulation layers are formed.

### BRIEF DESCRIPTION OF THE FIGURES

The above and other aspects of the present disclosure will become apparent by describing in detail embodiments thereof with reference to the accompanying drawings.

FIG. 1 is a block diagram of an electronic device according to one or more embodiments of the present disclosure.

FIG. 2 is a schematic view of various electronic devices according to one or more embodiments of the present disclosure.

FIG. 3 is a perspective view of a coupling state of the electronic device according to one or more embodiments of the present disclosure.

FIG. 4 is an exploded perspective view of the electronic device according to one or more embodiments of the present disclosure.

FIG. 5A is a cross-sectional view of a display panel according to one or more embodiments of the present disclosure.

FIG. 5B is a cross-sectional view of the display panel according to one or more embodiments of the present disclosure.

FIG. 6 is a cross-sectional view of a display panel according to one or more embodiments of the present disclosure.

FIGS. 7A-15B are views illustrating operations of a method of manufacturing a display panel according to the present disclosure.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

In the drawings, the relative sizes of elements, layers, and regions may be exaggerated for clarity and/or descriptive purposes. In other words, because the sizes and thicknesses of elements in the drawings are arbitrarily illustrated for convenience of description, the disclosure is not limited thereto. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “over,” “higher,” “upper side,” “side” (e.g., as in “sidewall”), and the like, may be used herein for ease of explanation to describe one element or feature’s relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component (e.g., an apparatus, a device, a circuit, a wire, an electrode, a terminal, a conductive film, etc.) is referred to as being “formed on,” “on,” “connected to,” or “(operatively, functionally, or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a transistor, a resistor, an inductor, a capacitor, a diode and/or the like. Accordingly, a connection is not limited to the connections illustrated in the drawings or the detailed description and may also include other types of connections. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XY, YZ, and XZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list. When "C to D" is stated, it means C or more and D or less, unless otherwise specified.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are only used to distinguish one element, member, component, region, area, layer, section, or portion from another element, member, component, region, area, layer, section, or portion. Thus, a first element, component, region, layer, or section described below could be termed a second element, component, region, layer, or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

When one or more embodiments may be implemented differently, a specific process order may be performed differently from the described order. For example, two consecutively described processes may be performed substantially at the same time or performed in an order opposite to the described order.

As used herein, the terms “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/- 5 % of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ± 30%, 20%, 10%, 5% of the stated value. Further, the use of “may” when describing embodiments of the present disclosure refers to “one or more embodiments of the present disclosure.” Furthermore, the expression “being the same” may mean “being substantially the same.” In other words, the expression “being the same” may include a range that can be tolerated by those of ordinary skill in the art. The other expressions may also be expressions from which “substantially” has been omitted.

In some embodiments well-known structures and devices may be described in the accompanying drawings in relation to one or more functional blocks (e.g., block diagrams), units, and/or modules to avoid unnecessarily obscuring various embodiments. Those skilled in the art will understand that such block, unit, and/or module are/is physically implemented by a logic circuit, an individual component, a microprocessor, a hard wire circuit, a memory element, a line connection, and other electronic circuits. This may be formed using a semiconductor-based manufacturing technique or other manufacturing techniques. The block, unit, and/or module implemented by a microprocessor or other similar hardware may be programmed and controlled using software to perform various functions discussed herein, optionally may be driven by firmware and/or software. In addition, each block, unit, and/or module may be implemented by dedicated hardware, or a combination of dedicated hardware that performs some functions and a processor (for example, one or more programmed microprocessors and related circuits) that performs a function different from those of the dedicated hardware. In addition, in some embodiments, the block, unit, and/or module may be physically separated into two or more interact individual blocks, units, and/or modules without departing from the scope of the present disclosure. In addition, in some embodiments, the block, unit and/or module may be physically combined into more complex blocks, units, and/or modules without departing from the scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

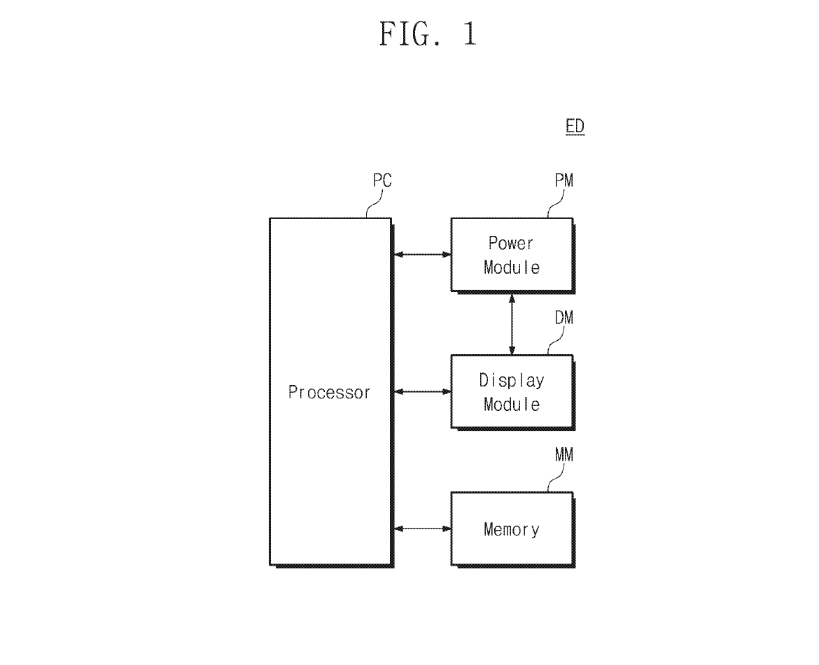

FIG. 1 is a block diagram of an electronic device according to one or more embodiments of the present disclosure.

Referring to FIG. 1, an electronic device ED according to one or more embodiments of the present disclosure may include a display module DM, a processor PC, a memory MM, and a power module PM.

The processor PC may include at least one of a central processing unit (CPU), an application processor (AP), a graphic processing unit (GPU), a communication processor (CP), an image signal processor (ISP), or a controller.

Data information required for operating the processor PC or the display module DM may be stored in the memory MM. When the processor PC executes an application stored in the memory MM, an image data signal and/or an input control signal may be transmitted to the display module DM, and the display module DM may process the received signal and output image information through a display screen.

The power module PM may include a power supply module, such as a power adapter or a battery device, and a power conversion module that converts power supplied by the power supply module to generate power required for operating the electronic device ED.

At least one of the components of the electronic device ED may be included in a display device according to one or more embodiments, which will be described below. Further, some of individual modules functionally included inside one module may be included inside the display device, and the others thereof may be provided separately from the display device. For example, the display device may include the display module DM, and the processor PC, the memory MM, and the power module PM may be provided in the form of other devices in the electronic device ED rather than the display device.

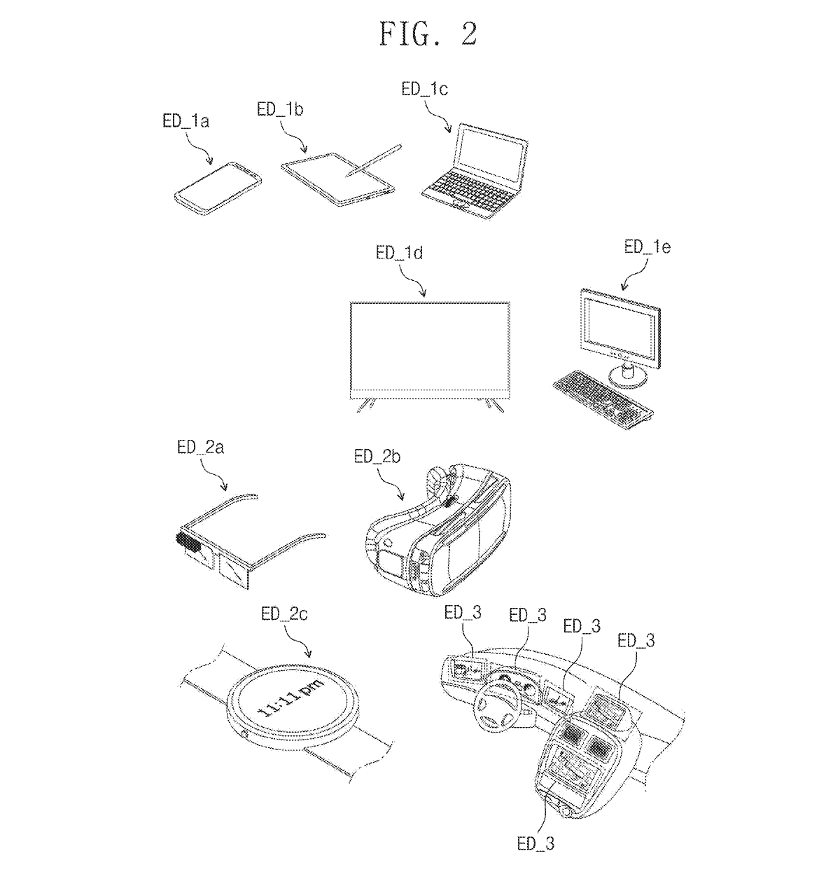

FIG. 2 is a schematic view of various electronic devices according to one or more embodiments of the present disclosure.

Referring to FIG. 2, the electronic device according to one or more embodiments of the present disclosure may include an image display electronic device, such as a smart phone ED-1a, a tablet PC ED-1b, a laptop ED-1c, a TV ED-1d, and/or a desk monitor ED-1e, a wearable electronic device, such as smart glasses ED-2a, a head-mounted display ED-2b, and/or a smart watch ED-2c, and/or a vehicle electronic device ED-3, such as an instrument panel, a center fascia, a center information display (CID) located on a dashboard, and/or a room mirror display of a vehicle.

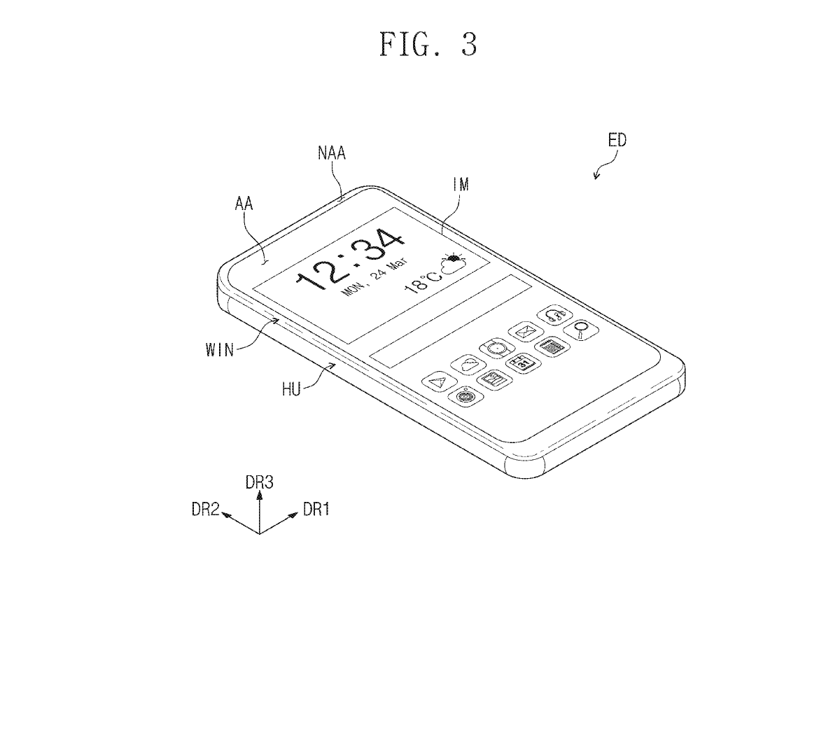

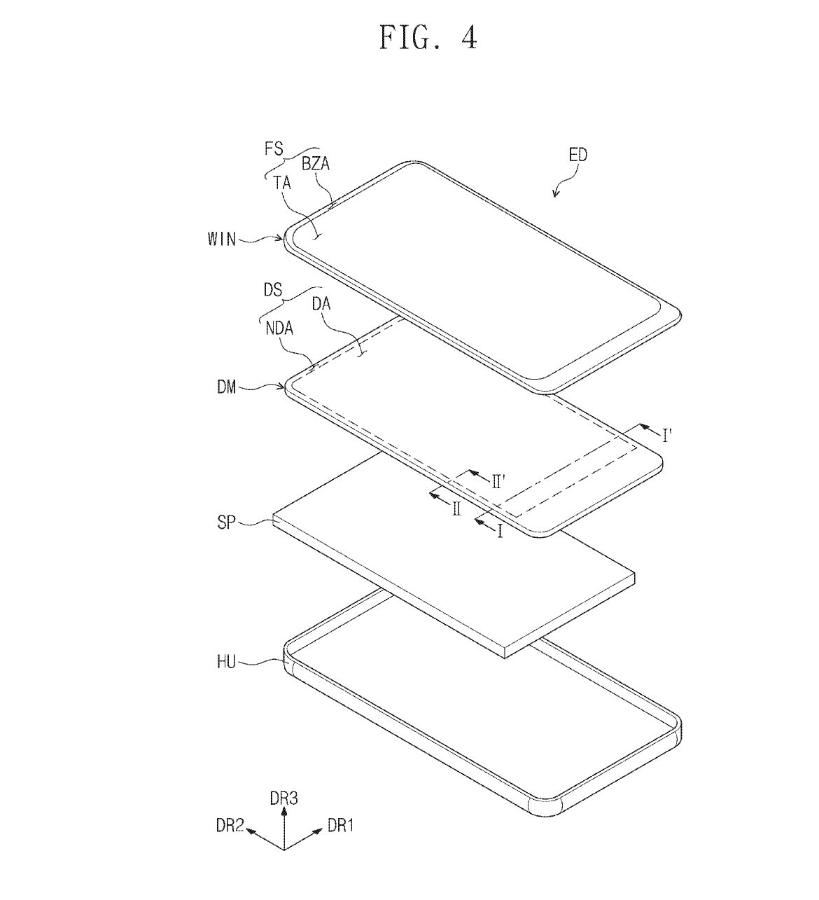

FIG. 3 is a perspective view of a coupling state of the electronic device according to one or more embodiments of the present disclosure. FIG. 4 is an exploded perspective view of the electronic device according to one or more embodiments of the present disclosure.

The electronic device ED according to one or more embodiments may be a device that is activated according to an electrical signal. For example, the electronic device ED may be a television, an external billboard, a monitor, a mobile phone, a tablet, a car navigation device, a game machine, or a wearable device, but one or more embodiments is not limited thereto. FIG. 3 illustrates, by way of example, that the electronic device ED is a mobile phone.

In the specification, a direction substantially perpendicular to a plane defined by a first direction DR1 and a second direction DR2 is defined as a third direction DR3. Further, in the specification, the meaning of “on a plane” or “in plan view” is defined as a state of being viewed in the third direction DR3 or in a thickness direction. The directions indicated by the first direction axis DR1, the second direction axis DR2, and the third direction axis DR3 are relative concepts and may be changed to other directions. Hereinafter, the first to third directions refer to the same reference numerals as the directions are indicated by the first direction DR1, the second direction DR2, and the third direction DR3, respectively.

In the specification, an upper surface (or a front surface) and a lower surface (or a rear surface) of each member are defined with respect to a direction in which an image IM is displayed. The upper surface and the lower surface may be opposite to each other in the third direction axis DR3, and a normal direction of the upper surface and the lower surface may be parallel to the third direction axis DR3.

Referring to FIG. 3, the electronic device ED according to one or more embodiments may include an active area AA and a peripheral area NAA. The active area AA of the electronic device ED may display the image IM. The image IM may include a still image as well as a dynamic image. In FIG. 3, a watch and a plurality of icons are illustrated as an example of the image IM. In the electronic device ED according to one or more embodiments, the active area AA may be a part corresponding to a display area DA of the display module DM, and the peripheral area NAA may be a part corresponding to a non-display area NDA of the display module DM.

The electronic device ED may display the image IM in the third direction DR3 on a display surface parallel to a plane defined by the first direction axis DR1 and the second direction axis DR2. The display surface on which the image IM is displayed may correspond to the upper surface of the electronic device ED and may correspond to an upper surface FS of a window WIN. Further, the electronic device ED may have a three-dimensional shape having a thickness (e.g., a predetermined thickness) in the third direction DR3, which is a direction perpendicular to the plane defined by the first direction axis DR1 and the second direction axis DR2.

The active area AA may have a quadrangular shape parallel to the plane defined by the first direction axis DR1 and the second direction axis DR2. However, this is illustrated by way of example, the active area AA may have various shapes, and the present disclosure is not limited to one or more embodiments.

The peripheral area NAA, which is an area that shields light, may be an area located outside the active area AA to surround the active area AA (e.g., in plan view). In one or more embodiments, the peripheral area NAA may be located on a side surface of the electronic device ED rather than a front surface thereof. In one or more embodiments, the peripheral area NAA may be omitted.

The electronic device ED according to one or more embodiments of the present disclosure may be rigid or flexible.

Referring to FIG. 4, the electronic device ED according to one or more embodiments of the present disclosure may include the display module DM that generates the image IM.

FIG. 4 illustrates, by way of example, the flat display module DM, but the display module DM may have a curved shape, may be folded, may be rolled, or may slide from a housing HU.

In the electronic device ED according to one or more embodiments of the present disclosure, the display module DM may include the display area DA and the non-display area NDA surrounding the display area DA. That is, an upper surface DS of the display module DM may include the display area DA and the non-display area NDA. The upper surface DS of the display module DM may be referred to as a display surface. The display area DA may be an area that is activated according to an electric signal.

The non-display area NDA may be adjacent to the display area DA. The non-display area NDA may surround the display area DA. Accordingly, a shape of the display area DA may be substantially defined by the non-display area NDA. However, this is illustrated by way of example, and the non-display area NDA may be adjacent to only one side of the display area DA or may be omitted. The electronic device ED according to one or more embodiments of the present disclosure may include the display area DA having various shapes, and is not limited to one or more embodiments.

Driving circuits or driving wiring lines for driving the display area DA, and various signal lines, pads, electronic elements, or the like for providing an electrical signal to the display area DA may be arranged in the non-display area NDA.

The electronic device ED according to one or more embodiments may further include an input sensor that senses an external input. The external input may include various types of inputs provided from the outside of the electronic device ED. For example, the external input may include a contact by a part of a body of the user, such as a hand, as well as an external input (e.g., hovering) applied close to the electronic device ED or adjacent to the electronic device ED at a distance (e.g., a predetermined distance). Further, the external input may have various forms, such as a force, a pressure, a temperature, and light.

The electronic device ED according to one or more embodiments of the present disclosure may further include the window WIN located on the display module DM (as used herein, “located on” may mean “above”). Further, the electronic device ED according to one or more embodiments may further include a support member SP and/or the housing HU located under the display module DM. In the electronic device ED according to one or more embodiments illustrated in FIGS. 3 and 4, the window WIN and the housing HU may be coupled to each other to constitute an external appearance of the electronic device ED.

The window WIN includes the upper surface FS exposed to the outside. A transmissive area TA on the upper surface FS of the window WIN may be an optically transparent area. The transmissive area TA may have a shape corresponding to the display area DA of the display module DM. For example, the transmissive area TA overlaps the front surface or at least a portion of the display area DA. An image displayed on the display area DA of the display module DM may be visually recognized from the outside through the transmissive area TA.

A bezel area BZA of the window WIN may be adjacent to the transmissive area TA, and may surround the transmissive area TA. The bezel area BZA may cover the non-display area NDA of the display module DM, and may reduce or prevent visual recognition of the non-display area NDA from the outside.

The electronic device ED according to one or more embodiments of the present disclosure may include the support member SP located under the display module DM. The support member SP may include a cushion layer and/or a metal support layer.

The window WIN and the housing HU may be coupled to each other to constitute an external appearance of the electronic device ED. The window WIN and the housing HU may be coupled to each other to form an internal space for accommodating components, such as the display module DM. The display module DM, the support member SP, and the like may be accommodated in the internal space.

The housing HU may include a material having relatively high rigidity. For example, the housing HU may include a frame and/or a plate including glass, plastic, or metal or formed of a combination thereof. The housing HU may protect the display module DM accommodated in the housing HU by absorbing an impact applied from the outside or reducing or preventing foreign substances/moisture penetrating from the outside.

The electronic device ED according to one or more embodiments of the present disclosure may further include various electronic modules. For example, the electronic module may include at least one of a camera, a speaker, a light-sensing sensor, or a heat-sensing sensor. The electronic module may sense an external subject received from the outside or provide a sound signal, such as voice to the outside. The electronic module may include a plurality of components, and the present disclosure is not limited to one or more embodiments.

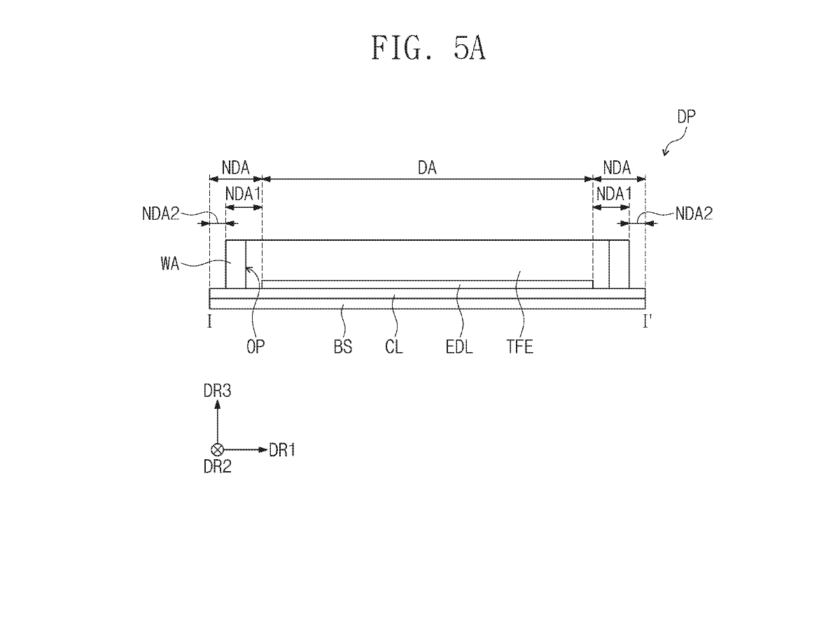

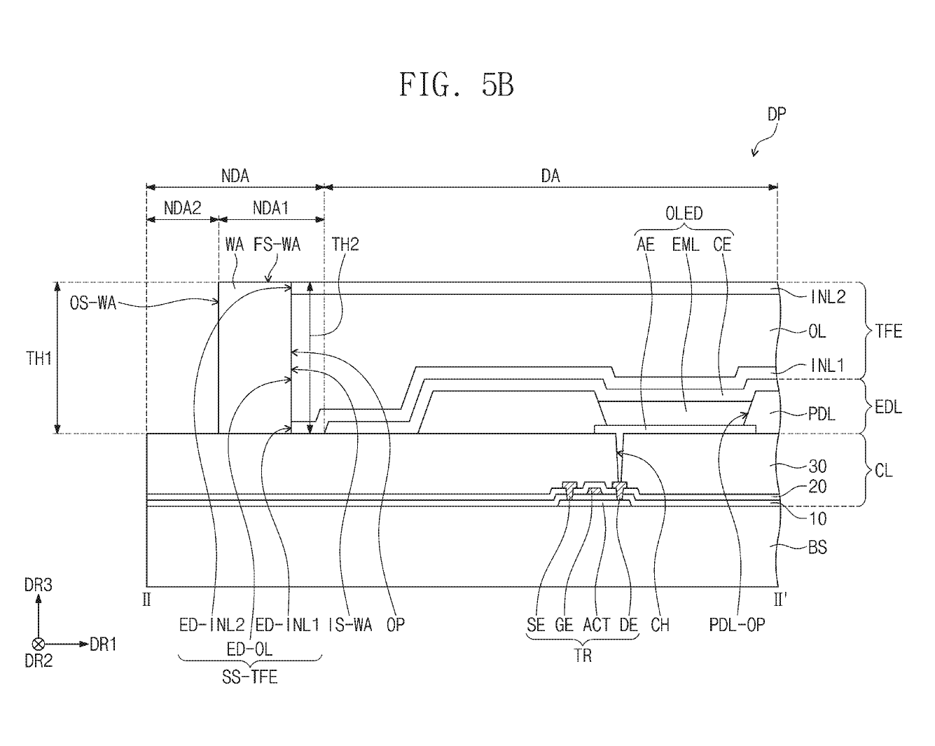

FIG. 5A is a cross-sectional view of a display panel according to one or more embodiments of the present disclosure.

The display module DM (see FIG. 4) may include a display panel DP that generates an image. FIG. 5A is a cross-sectional view of the display panel DP included in the display module DM (see FIG. 4) according to one or more embodiments of the present disclosure. In detail, FIG. 5A is a cross-sectional view of the display panel DP included in the display module DM (see FIG. 4) along the line I-I' illustrated in FIG. 4.

Referring to FIG. 5A, the display panel DP may include the display area DA, and the non-display area NDA surrounding the display area DA (e.g., in plan view). The display area DA of the display panel DP may be defined as an area in which a light-emitting element layer EDL is located. Further, the display area DA and the non-display area NDA of the display panel DP may correspond to the display area DA and the non-display area NDA of the display module DM (see FIG. 4), respectively.

The non-display area NDA may include a first non-display area NDA1 overlapping a partition wall WA, and a second non-display area NDA2 surrounding the first non-display area NDA1 (e.g., in plan view). The first non-display area NDA1 may be defined as an area that overlaps the partition wall WA, and is adjacent to the display area DA. The second non-display area NDA2 may be defined as an area that does not overlap the partition wall WA, and surrounds the first non-display area NDA1. The second non-display area NDA2 may be spaced apart from the display area DA. According to one or more embodiments of the present disclosure, the first non-display area NDA1 may overlap an encapsulation layer TFE. Further, the second non-display area NDA2 might not overlap the partition wall WA (e.g., may be spaced from the partition wall WA in plan view). Further, the second non-display area NDA2 might not overlap some layers included in the encapsulation layer TFE. For example, the second non-display area NDA2 might not overlap a first inorganic layer INL1 (see FIG. 5B) and an organic layer OL (see FIG. 5B). A detailed description thereof will be provided below.

The display panel DP may include a base substrate BS, a circuit element layer CL, the light-emitting element layer EDL, the partition wall WA, and the encapsulation layer TFE.

The base substrate BS may provide a base surface on which the circuit element layer CL is located. The base substrate BS may be a rigid substrate, or may be a flexible substrate that may be bent, folded, or rolled.

The base substrate BS may include a plastic substrate, a glass substrate, a metal substrate, an organic/inorganic composite material substrate, or the like. The base substrate BS may have a multi-layer structure. For example, the base substrate BS may include an inorganic layer, a synthetic resin layer, or a composite material layer. The synthetic resin layer may be a polyimide-based resin layer, and a material thereof is not particularly limited thereto. The synthetic resin layer may include at least one of an acryl-based resin, a methacryl-based resin, a polyisoprene, a vinyl-based resin, an epoxy-based resin, a urethane-based resin, a cellulose-based resin, a siloxane-based resin, a polyamide-based resin, or a perylene-based resin.

The circuit element layer CL may be located on the base substrate BS. The circuit element layer CL may include at least one insulating layer, a semiconductor pattern, and a conductive pattern. After an insulating layer, a semiconductor layer, and a conductive layer are formed through coating, deposition, or the like, the insulating layer, the semiconductor layer, and the conductive layer may be patterned through a photolithography process and an etching process multiple times, and thus the insulating layer, the semiconductor pattern, and the conductive pattern of the circuit element layer CL may be formed. The insulating layer, the semiconductor pattern, and the conductive pattern included in the circuit element layer CL may form driving elements, such as transistors, signal lines, and pads in the circuit element layer CL.

The light-emitting element layer EDL may be located on the circuit element layer CL. The light-emitting element layer EDL may include light-emitting elements OLED. The light-emitting elements OLED of the light-emitting element layer EDL may be electrically connected to the driving elements of the circuit element layer CL to generate light according to signals provided by the driving elements so as to display an image. The light-emitting element OLED may be an organic light-emitting element, an inorganic light-emitting element, an organic-inorganic light-emitting element, a micro light-emitting diode (LED), a nano LED, a quantum dot light-emitting element, an electrophoretic element, an electrowetting element, or the like.

The partition wall WA may be located on the circuit element layer CL. The partition wall WA may overlap the non-display area NDA. The partition wall WA may include/define an opening OP surrounding the display area DA. A detailed description of the partition wall WA will be provided below.

The encapsulation layer TFE may be located on the light-emitting element layer EDL. The encapsulation layer TFE may overlap the display area DA in which the light-emitting element layer EDL is located. The encapsulation layer TFE may extend to overlap a portion of the non-display area NDA. For example, according to one or more embodiments, the encapsulation layer TFE may overlap the first non-display area NDA1. Further, the encapsulation layer TFE may cover the light-emitting element layer EDL. The encapsulation layer TFE may protect the light-emitting element layer EDL from foreign substances, such as moisture, oxygen, and dust particles. A detailed description of the encapsulation layer TFE according to one or more embodiments of the present disclosure will be provided below.

A laminated configuration and a laminated order of the display panel DP illustrated in FIG. 5A are by way of example, and the present disclosure is not limited thereto. For example, the display panel DP may further include an optical member or the like located on the encapsulation layer TFE.

FIG. 5B is a cross-sectional view of the display panel according to one or more embodiments of the present disclosure.

FIG. 5B is a cross-sectional view of the display panel DP along the line II-II′ illustrated in FIG. 4 according to one or more embodiments of the present disclosure.

The base substrate BS may be a member that provides a base surface on which the circuit element layer CL is located. The base substrate BS may include the display area DA and the non-display area NDA. The display area DA and the non-display area NDA of the base substrate BS may correspond to the display area DA and the non-display area NDA of the display panel DP, respectively.

The circuit element layer CL may include a first insulating layer 10, a second insulating layer 20, a third insulating layer 30, and a transistor TR. Further, in one or more embodiments, the circuit element layer CL may include a power electrode, signal lines, a signal line providing an initialization voltage, a connection electrode, and the like.

The first insulating layer 10 may be located on the base substrate BS, the second insulating layer 20 may be located on the first insulating layer 10, and the third insulating layer 30 may be located on the second insulating layer 20. The first insulating layer 10 and the second insulating layer 20 may include inorganic films. The third insulating layer 30 may include an organic film. In one or more embodiments, the circuit element layer CL may further include a buffer layer located between the base substrate BS and the first insulating layer 10. The buffer layer may include an inorganic film. The buffer layer may include a plurality of inorganic films.

The transistor TR may include a semiconductor layer ACT. The semiconductor layer ACT may be located between the base substrate BS and the first insulating layer 10. The first insulating layer 10 may cover the semiconductor layer ACT. The semiconductor layer ACT may include a plurality of areas classified according to whether a metal oxide is reduced. An area (hereinafter, referred to as a reduced area) in which the metal oxide is reduced may have greater conductivity than an area in which the metal oxide is not reduced (hereinafter, referred to as a non-reduced area). The reduced area may substantially serve as a source/drain or a signal line of the transistor TR. The non-reduced area may substantially correspond to an active area (or a semiconductor area or a channel area) of the transistor TR. In other words, a portion of the transistor TR may be an active area of the transistor, another portion thereof may be a source area/drain area of the transistor, and still another portion thereof may be a signal transmission area.

A gate electrode GE may be located on the first insulating layer 10. The gate electrode GE may include a conductive material including molybdenum (Mo), aluminum (Al), copper (Cu), titanium (Ti), or the like and may be a single layer or a plurality of layers including the materials. The second insulating layer 20 may cover the gate electrode GE.

A source electrode SE and a drain electrode DE may be located on the second insulating layer 20. The source electrode SE and the drain electrode DE may be connected to a source area and a drain area of the semiconductor layer ACT through a contact hole, respectively. The third insulating layer 30 may be located on the source electrode SE and the drain electrode DE. The third insulating layer 30 may cover the source electrode SE and the drain electrode DE.

However, the circuit element layer CL illustrated in FIG. 5B is by way of example, but the present disclosure is not limited thereto, and other components may be further included.

The light-emitting element layer EDL may be located on the circuit element layer CL. The light-emitting element layer EDL may include the light-emitting element OLED and a pixel-defining film PDL. The light-emitting element OLED may include a first electrode AE, a light-emitting layer EML, and a second electrode CE.

The first electrode AE may be located on the circuit element layer CL. The first electrode AE may be connected to the drain electrode DE through a contact hole CH passing through the third insulating layer 30. The first electrode AE may be an anode electrode.

The first electrode AE may be a transmissive electrode, a semi-transmissive electrode, or a reflective electrode. When the first electrode AE is the transmissive electrode, the first electrode AE may include a transparent metal oxide, for example, an indium tin oxide (ITO), an indium zinc oxide (IZO), a zinc oxide (ZnO), an indium tin zinc oxide (ITZO) or the like. When the first electrode AE is a semi-transmissive electrode or a reflective electrode, the first electrode AE may include Ag, Mg, Cu, Al, Pt, Pd, Au, Ni, Nd, Ir, Cr, Li, Ca, LiF/Ca (a laminated structure of LiF and Ca), LiF/Al (a laminated structure of LiF and Al), Mo, Ti, W, or a compound or mixture thereof (e.g., a mixture of Ag and Mg). Alternatively, the first electrode AE may have a multi-layer structure including a reflective film or a semi-transmissive film formed of the above material and a transparent conductive film formed of an indium tin oxide (ITO), an indium zinc oxide (IZO), a zinc oxide (ZnO), and an indium tin zinc oxide (ITZO). For example, the first electrode AE may have a three-layer structure of ITO/Ag/ITO, but the present disclosure is not limited thereto.

The pixel-defining film PDL may be located on the circuit element layer CL. The pixel-defining film PDL may be located on the same layer as the first electrode AE. The pixel-defining film PDL may include/define a light-emitting opening PDL-OP. The light-emitting opening PDL-OP may expose at least a portion of the first electrode AE.

The pixel-defining film PDL may include a polymer resin. For example, the pixel-defining film PDL may include a polyacrylate-based resin or a polyimide-based resin. Further, the pixel-defining film PDL may further include an inorganic material in addition to the polymer resin. Further, the pixel-defining film PDL may include a light absorbing material or may include a black pigment or a black dye. The pixel-defining film PDL including the black pigment or the black dye may implement a black pixel-defining film. Carbon black may be used as the black pigment or the black dye, but one or more embodiments is not limited thereto.

In one or more embodiments, a spacer overlapping a portion of the pixel-defining film PDL may be located on an upper surface of the pixel-defining film PDL. The spacer may be an insulating structure having an integral shape with the pixel-defining film PDL or formed by an additional process.

The light-emitting layer EML may be located on the first electrode AE. Although FIG. 5B illustrates one light-emitting opening PDL-OP, the pixel-defining film PDL may include the plurality of light-emitting openings PDL-OP, and the light-emitting layers EML may be arranged on the plurality of light-emitting openings PDL-OP, respectively. Each of the light-emitting layers EML may emit light having at least one color among red, green, and blue. However, one or more embodiments is not limited thereto.

The light-emitting layer EML may include a fluorescent or phosphorescent organic material that emits red light, green light, or blue light. Further, the light-emitting layer EML may include a metal organic complex as a light-emitting material. Further, the light-emitting layer EML may include a quantum dot as a light-emitting material. However, one or more embodiments is not limited thereto.

In one or more embodiments, the light-emitting element OLED may further include a hole transport area and an electron transport area. The hole transport area may be located between the first electrode AE and the light-emitting layer EML. The hole transport area may include a hole transport layer, and may further include a hole injection layer. The electron transport area may be located between the light-emitting layer EML and the second electrode CE. The electron transport area may include an electron transport layer, and may further include an electron injection layer. The hole transport area and the electron transport area may be commonly arranged in the light-emitting areas and a non-light-emitting area surrounding the light-emitting areas. However, one or more embodiments is not limited thereto, and the hole transport area and the electron transport area may be patterned to correspond to the light-emitting areas.

The second electrode CE may be located on the light-emitting layer EML. The second electrode CE may be formed as a common layer using an open mask. The second electrode CE may be a cathode electrode.

The second electrode CE may be a transmissive electrode, a semi-transmissive electrode, or a reflective electrode. When the second electrode CE is a transmissive electrode, the second electrode CE may be formed of a transparent metal oxide, for example, an indium tin oxide (ITO), an indium zinc oxide (IZO), a zinc oxide (ZnO), an indium tin zinc oxide (ITZO), or the like. When the second electrode CE is a semi-transmissive electrode or a reflective electrode, the second electrode CE may include Ag, Mg, Cu, Al, Pt, Pd, Au, Ni, Nd, Ir, Cr, Li, Ca, LiF/Ca (a laminated structure of LiF and Ca), LiF/Al (a laminated structure of LiF and Al), Mo, Ti, Yb, W, or a compound or mixture (e.g., AgMg, AgYb, or MgYb) including the same. Alternatively, the second electrode CE may have a multi-layer structure including a reflective film or a semi-transmissive film formed of the above material and a transparent conductive film formed of an indium tin oxide (ITO), an indium zinc oxide (IZO), a zinc oxide (ZnO), and an indium tin zinc oxide (ITZO). For example, the second electrode CE may include the above-described metal materials, a combination of two or more metal materials selected from the above-described metal materials, an oxide of the above-described metal materials, or the like. However, one or more embodiments is not limited thereto.

In one or more embodiments, the light-emitting element layer EDL may further include a capping layer located on the light-emitting element OLED. The capping layer may be located on the second electrode CE. The capping layer may include a single layer or a plurality of layers. However, the capping layer may be omitted.

The partition wall WA may be located on the circuit element layer CL. The partition wall WA may be directly located on the circuit element layer CL. The partition wall WA may be located on the same layer as the light-emitting element layer EDL. The partition wall WA may overlap the non-display area NDA. In detail, the partition wall WA may overlap the first non-display area NDA1. Further, the partition wall WA may be adjacent to the display area DA and the encapsulation layer TFE.

The partition wall WA may be spaced apart from the light-emitting element layer EDL on a plane. The partition wall WA may surround the light-emitting element layer EDL on a plane. Accordingly, the partition wall WA may include the opening OP surrounding the display area DA. Further, the partition wall WA may surround the encapsulation layer TFE on a plane. Accordingly, the encapsulation layer TFE may be located inside the opening OP of the partition wall WA. The partition wall WA may be located in the non-display area NDA and serve to guide the encapsulation layer TFE such that the encapsulation layer TFE is located inside the opening OP of the partition wall WA. The encapsulation layer TFE may be located inside the opening OP of the partition wall WA, and the partition wall WA may contact a side surface SS-TFE of the encapsulation layer TFE. Accordingly, the first inorganic layer INL1, the organic layer OL, and a second inorganic layer INL2 included in the encapsulation layer TFE may be arranged inside the opening OP of the partition wall WA and may contact a side surface of the partition wall WA.

A cross-sectional shape of the partition wall WA may be rectangular. The partition wall WA may include a lower surface adjacent to the circuit element layer CL, an upper surface FS-WA opposite to the lower surface, and a side surface connecting the upper surface FS-WA and the lower surface. The side surface of the partition wall WA may include an inner side surface IS-WA corresponding to the opening OP and an outer side surface OS-WA opposite to the inner side surface IS-WA.

The inner side surface IS-WA and the outer side surface OS-WA of the partition wall WA may be perpendicular to a plane parallel to the base substrate BS (e.g., may be substantially perpendicular to the base substrate BS). That is, the inner side surface IS-WA and the outer side surface OS-WA of the partition wall WA may be perpendicular (e.g., substantially perpendicular) to the plane defined by the first direction DR1 and the second direction DR2. Here, the term “vertical” is not limited to a theoretical right angle (90°), but may be a concept including an inclination within an allowable angular error range that may occur in a manufacturing process. The term “vertical” used herein has the same meaning as long as the term is repeatedly used below unless otherwise mentioned. The partition wall WA is formed in an imprint method, so that the inner side surface IS-WA and the outer side surface OS-WA of the partition wall WA may be vertical compared to a case in which the partition wall WA is formed in an etching method or the like. Further, the inner side surface IS-WA of the partition wall WA may be spaced apart from the light-emitting element layer EDL. Further, the inner side surface IS-WA of the partition wall WA may contact the side surface SS-TFE of the encapsulation layer TFE. Accordingly, the inner side surface IS-WA of the partition wall WA may be a surface corresponding to the side surface SS-TFE of the encapsulation layer TFE.

The upper surface FS-WA of the partition wall WA may be spaced apart from the circuit element layer CL. The upper surface FS-WA of the partition wall WA may be a plane parallel to the base substrate BS (e.g., may be substantially parallel to the base substrate BS). That is, the upper surface FS-WA may be parallel to the plane defined by the first direction DR1 and the second direction DR2. Further, the upper surface FS-WA of the partition wall WA may be flat. The partition wall WA may be formed in an imprint method, and the upper surface FS-WA of the partition wall WA may have a flat planar shape compared to a case in which the partition wall WA is formed in a photoresist process or the like.

A lower surface of the partition wall WA may contact the circuit element layer CL. The lower surface of the partition wall WA may be directly located on the circuit element layer CL. Accordingly, a shape of the lower surface of the partition wall WA may correspond to an overlapping portion of a shape of an upper surface of the circuit element layer CL spaced apart from the base substrate BS.

The partition wall WA may serve to guide the organic layer OL such that the organic layer OL is formed inside the opening OP of the partition wall WA. Thus, a thickness TH1 of the partition wall WA may be designed in consideration of a thickness TH2 of the encapsulation layer TFE including the organic layer OL. For example, the thickness TH1 of the partition wall WA may be equal to or greater than the thickness TH2 of the encapsulation layer TFE to reduce or prevent overflow of a fluidic organic material used to form the organic layer OL. Here, the thickness TH1 of the partition wall WA and the thickness TH2 of the encapsulation layer TFE may be defined as a length measured in the third direction DR3.

The partition wall WA may include an organic material. The partition wall WA may be formed from a resin. For example, the partition wall WA may be formed from a photocurable resin. Further, the partition wall WA may include a material capable of reducing or preventing penetration of oxygen and moisture. Accordingly, when the partition wall WA is formed from the resin capable of reducing or preventing the penetration of oxygen and moisture, the partition wall WA may protect the organic layer OL from oxygen and moisture. For example, the partition wall WA may be formed of a photocurable resin material capable of reducing or preventing the penetration of oxygen and moisture. The photocurable resin material capable of reducing or preventing the penetration of oxygen and moisture may include a urethane acrylate or a silicon acrylate, but this is by way of example, and the present disclosure is not limited thereto. The partition wall WA may be formed by patterning the resin in an imprint method and then curing the resin. A detailed description thereof will be provided below.

The encapsulation layer TFE may be located on the light-emitting element layer EDL. The encapsulation layer TFE may cover the light-emitting element layer EDL to protect the light-emitting element OLED from oxygen and moisture. Further, the encapsulation layer TFE may cover a step difference or a curve according to the light-emitting element layer EDL. For example, the organic layer OL may cover the step difference according to the light-emitting element layer EDL.

The encapsulation layer TFE may be located inside the opening OP of the partition wall WA. Accordingly, the encapsulation layer TFE may overlap the display area DA. Further, the encapsulation layer TFE may overlap not only the display area DA but also a portion of the non-display area NDA. In detail, the encapsulation layer TFE may overlap the display area DA and an area, in which the partition wall WA is not located, among the first non-display area NDA1, and may not overlap the second non-display area NDA2. Unlike FIG. 5B, when the partition wall WA and the light-emitting element layer EDL are not spaced apart from each other and are adjacent to each other, the encapsulation layer TFE may overlap only the display area DA and may not overlap the non-display area NDA including the first non-display area NDA1.

The encapsulation layer TFE may include a plurality of thin films. The encapsulation layer TFE may include the first inorganic layer INL1, the organic layer OL, and the second inorganic layer INL2. However, the present disclosure is not limited thereto, and the encapsulation layer TFE may further include other thin film layers.

The first inorganic layer INL1 may be located on the light-emitting element layer EDL. The first inorganic layer INL1 may serve to protect the light-emitting element OLED from oxygen and moisture. The first inorganic layer INL1 may include a silicon oxide, a silicon nitride, or a silicon oxy nitride. However, the material included in the first inorganic layer INL1 is not limited thereto.

The first inorganic layer INL1 may be located inside the opening OP of the partition wall WA. Accordingly, the first inorganic layer INL1 may not overlap the second non-display area NDA2. Further, the first inorganic layer INL1 may overlap a portion of the first non-display area NDA1. In detail, the first inorganic layer INL1 may overlap an area of the first non-display area NDA1, in which the partition wall WA is not located. Unlike FIG. 5B, when the partition wall WA and the light-emitting element layer EDL are not spaced apart from each other and are adjacent to each other, the first inorganic layer INL1 may overlap only the display area DA and may not overlap the non-display area NDA including the first non-display area NDA1. The first inorganic layer INL1 may include a first edge ED-INL1 in contact with the inner side surface IS-WA of the partition wall WA. The first edge ED-INL1 may be perpendicular to the plane parallel to the base substrate BS.

The organic layer OL may be located on the first inorganic layer INL1. The organic layer OL may reduce or prevent inflow of an external material, and may provide a flat surface to the second inorganic layer INL2.

The organic layer OL may include a monomer-based material and/or a polymer-based organic material. The polymer-based material may include, for example, an acryl-based resin, an epoxy-based resin, polyimide, polyethylene, and the like. However, the material included in the organic layer OL is not limited thereto.

The organic layer OL may be located inside the opening OP of the partition wall WA. Accordingly, the organic layer OL may not overlap the second non-display area NDA2. Further, the organic layer OL may overlap a portion of the first non-display area NDA1. In detail, the organic layer OL may overlap an area of the first non-display area NDA1, in which the partition wall WA is not located. Unlike FIG. 5B, when the partition wall WA and the light-emitting element layer EDL are not spaced apart from

each other and are adjacent to each other, the organic layer OL may overlap only the display area DA and may not overlap the non-display area NDA including the first non-display area NDA1. The partition wall WA may serve to guide the organic layer OL of the encapsulation layer TFE such that the organic layer OL is formed inside the opening OP of the partition wall WA. For example, when the display panel DP is manufactured, a fluidic organic material may be applied to an inside of the opening OP of the partition wall WA to form the organic layer OL. Reflow of the organic material may not occur due to the partition wall WA, and thus the organic layer OL formed by curing the organic material may have a shape in which a taper is not included. Accordingly, the organic layer OL may include a second edge ED-OL in contact with the inner side surface IS-WA of the partition wall WA, and the second edge ED-OL may be perpendicular to the plane parallel to the base substrate BS.

Further, as the organic layer OL is located inside the opening OP of the partition wall WA, an area of the non-display area NDA may be reduced. The organic layer OL may be formed corresponding to a shape of the opening OP of the partition wall WA and reflow may not occur therein. Thus, the display panel DP may be designed in a structure in which the area of the non-display area NDA is reduced or minimized.

The second inorganic layer INL2 may be located on the organic layer OL. The second inorganic layer INL2 may cover the organic layer OL. The second inorganic layer INL2 may serve to protect the organic layer OL from oxygen and moisture. The second inorganic layer INL2 may include a silicon oxide, a silicon nitride, or a silicon oxy nitride. However, the material included in the second inorganic layer INL2 is not limited thereto.

The second inorganic layer INL2 may be located inside the opening OP of the partition wall WA. Accordingly, the second inorganic layer INL2 may not overlap the second non-display area NDA2. Further, the second inorganic layer INL2 may overlap a portion of the first non-display area NDA1. In detail, the second inorganic layer INL2 may overlap an area of the first non-display area NDA1, in which the partition wall WA is not located. Unlike FIG. 5B, when the partition wall WA and the light-emitting element layer EDL are not spaced apart from each other and are adjacent to each other, the second inorganic layer INL2 may overlap only the display area DA, and might not overlap the non-display area NDA including the first non-display area NDA1. The second inorganic layer INL2 may include a third edge ED-INL2 in contact with the inner side surface IS-WA of the partition wall WA. The third edge ED-INL2 may be perpendicular to the plane parallel to the base substrate BS (e.g. may be substantially perpendicular to the base substrate BS). The first edge ED-INL1, the second edge ED-OL, and the third edge ED-INL2 may be aligned.

When the encapsulation layer TFE is formed inside the opening OP of the partition wall WA, an angle between the inner side surface IS-WA of the partition wall WA and a plane parallel to the base substrate BS may be the same as an angle between the side surface SS-TFE of the encapsulation layer TFE in contact with the inner side surface IS-WA of the partition wall WA and a plane parallel to the base substrate BS. Accordingly, the angle between the inner side surface IS-WA of the partition wall WA and a plane parallel to the base substrate BS may be the same as an angle between the first edge ED-INL1, the second edge ED-OL, and the third edge ED-INL2 and a plane parallel to the base substrate BS.

The partition wall WA may guide the organic layer or the inorganic layer included in the encapsulation layer TFE such that the organic layer or the inorganic layer are aligned in the opening OP, and thus an inter-layer alignment error may be reduced or minimized. That is, the partition wall WA may allow the first edge ED-INL1, the second edge ED-OL, and the third edge ED-INL2 to be aligned and arranged. Further, the partition wall WA may reduce or minimize a problem in which a position of each layer is changed after the encapsulation layer TFE is formed. For example, a phenomenon in which the alignment of the first edge ED-INL1, the second edge ED-OL, and the third edge ED-INL2 is not maintained, or is changed, may be reduced or minimized. Accordingly, reliability of the display panel DP may be improved.

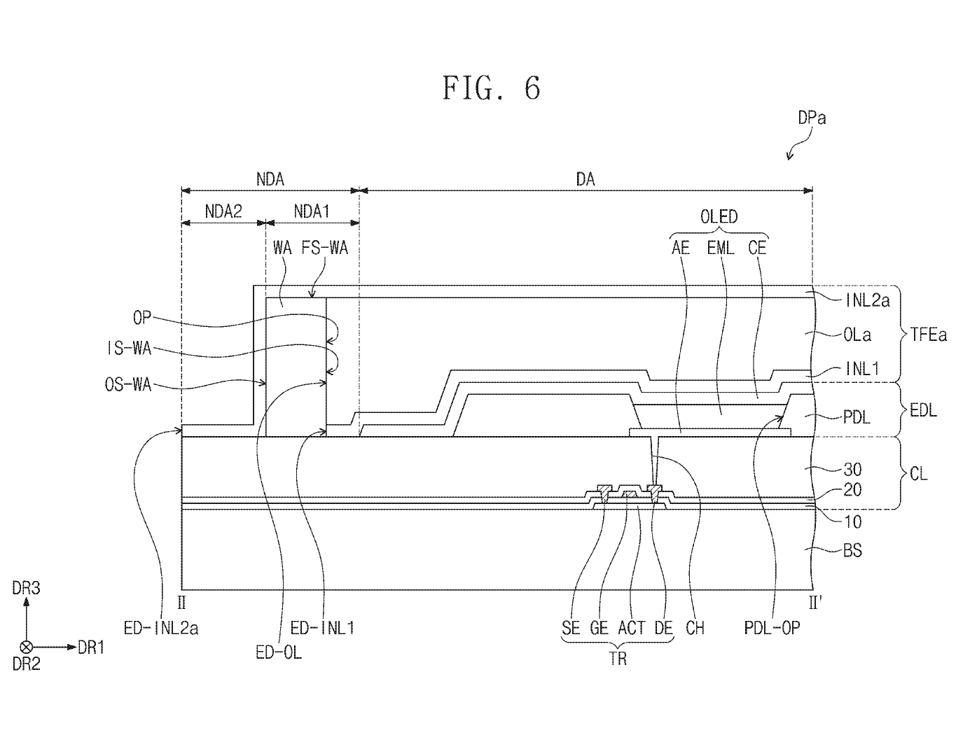

FIG. 6 is a cross-sectional view of a display panel according to one or more embodiments of the present disclosure.

FIG. 6 is a cross-sectional view of a display panel DPa along the line II-II′ illustrated in FIG. 4 according to one or more embodiments of the present disclosure. In FIG. 6, the same reference numerals are given to the same components as those described in FIGS. 1-5B, and duplicated descriptions thereof will be omitted. Hereinafter, a difference between FIGS. 6 and 5B will be mainly described.

Referring to FIG. 6, a second inorganic layer INL2a of an encapsulation layer TFEa may overlap the display area DA and the first non-display area NDA1. The second inorganic layer INL2a may cover at least a portion of the partition wall WA. For example, the second inorganic layer INL2a may cover the upper surface FS-WA of the partition wall WA. Accordingly, a third edge ED-INL2a might not contact the inner side surface IS-WA of the partition wall WA. Further, the second inorganic layer INL2a may overlap not only the display area DA and the first non-display area NDA1, but also may overlap the second non-display area NDA2 or a portion thereof. In detail, the second inorganic layer INL2a may extend to the second non-display area NDA2. Accordingly, the second inorganic layer INL2a may cover the upper surface FS-WA and the outer side surface OS-WA of the partition wall WA. When the second inorganic layer INL2a covers the upper surface FS-WA and the outer side surface OS-WA of the partition wall WA, materials other than materials capable of reducing or preventing the penetration of oxygen and moisture may also be used to form the partition wall WA.

However, the first inorganic layer INL1 and an organic layer OLa of the encapsulation layer TFEa may be arranged inside the opening OP of the partition wall WA. Accordingly, the first inorganic layer INL1 and the organic layer Ola may not overlap the non-display area NDA. For example, when the partition wall WA is in contact with the light-emitting element layer EDL, the first inorganic layer INL1 and the organic layer OLa may not overlap the non-display area NDA. Alternatively, the first inorganic layer INL1 and the organic layer OLa may overlap a portion of the first non-display area NDA1, and might not overlap the second non-display area NDA2. For example, as illustrated in FIG. 6, when the partition wall WA is spaced apart from the light-emitting element layer EDL, the first inorganic layer INL1 and the organic layer OLa may overlap an area of the first non-display area NDA1, in which the partition wall WA is not located, and might not overlap the second non-display area NDA2.

The organic layer OLa may be formed up to a position of the upper surface FS-WA of the partition wall WA. Accordingly, the organic layer OLa may provide a flat surface to the second inorganic layer INL2a. Further, the organic layer OLa is formed up to the position of the upper surface FS-WA of the partition wall WA, and thus a sum of a thickness of the first inorganic layer INL1, a thickness of the organic layer OLa, and a thickness of the second inorganic layer INL2a may be greater than a thickness of the partition wall WA. Further, a sum of the thicknesses of the first inorganic layer INL1 and the thickness of the organic layer OLa may be the same as, or substantially equal to, the thickness of the partition wall WA. Here, the thickness may be defined as a length measured in the third direction DR3.

The shapes of the second inorganic layers INL2 and INL2a illustrated in FIGS. 5A-6 are by way of example, and one or more embodiments may be provided as long as the second inorganic layers INL2 and INL2a may cover the organic layers OL and OLa.

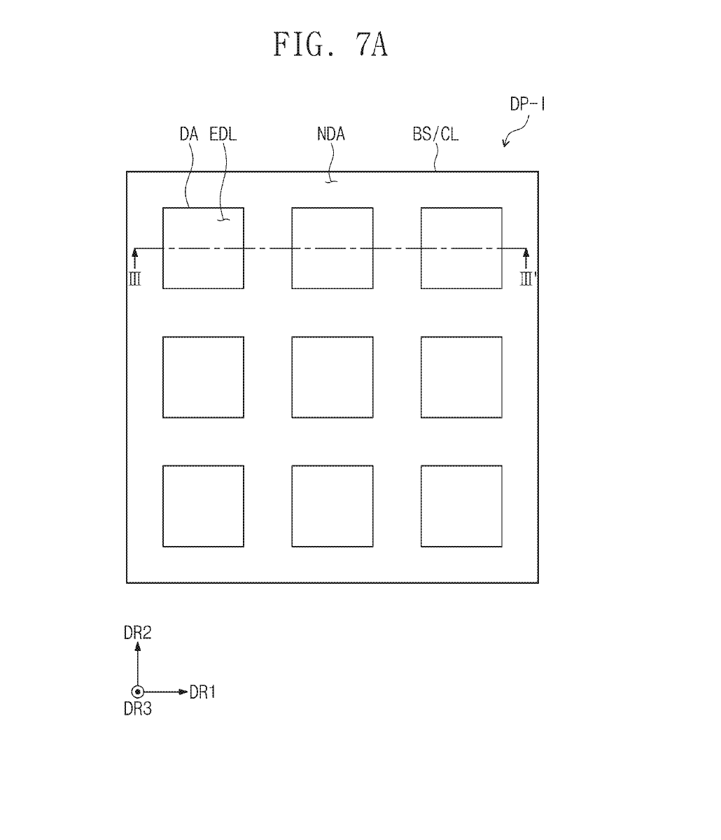

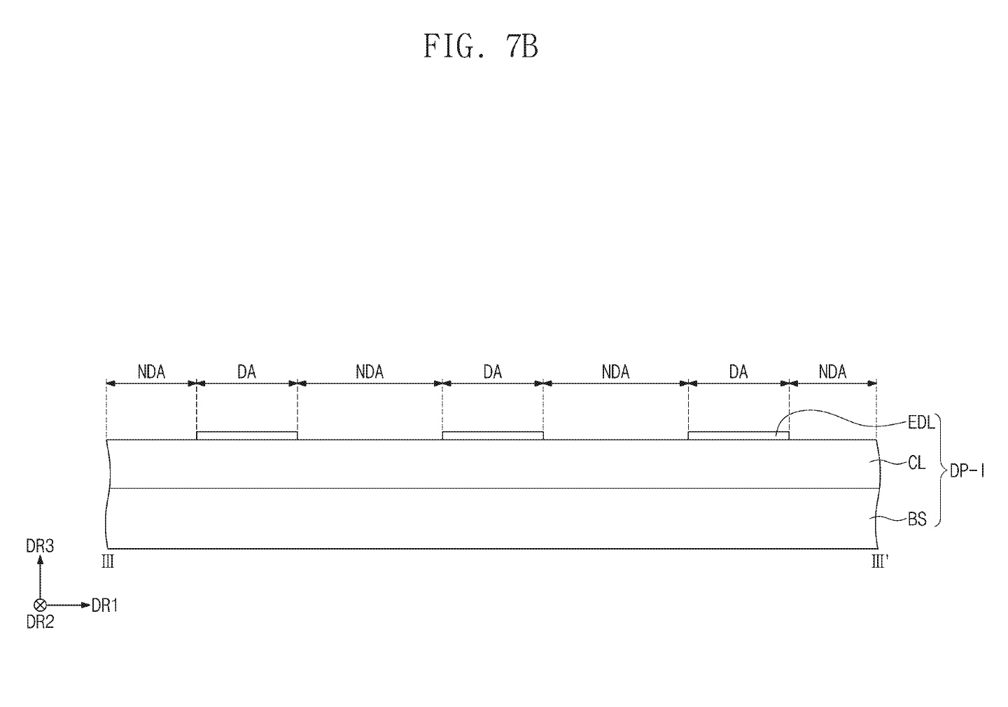

FIGS. 7A-15B are views illustrating operations of a method of manufacturing a display panel according to the present disclosure.

A method of manufacturing the display panel DP (see FIGS. 5B or 6) according to one or more embodiments of the present disclosure may include an operation of providing a preliminary display panel DP-I, an operation of forming the plurality of partition walls WA, and an operation of forming the encapsulation layer TFE. In FIGS. 7A-15B, the same reference numerals are assigned to the same components as those of FIGS. 1-6, and duplicated descriptions thereof will be omitted.

FIGS. 7A and 7B illustrate the operation of providing the preliminary display panel DP-I. FIG. 7A is a plan view illustrating the preliminary display panel DP-I, and FIG. 7B is a cross-sectional view along the line III-III' of FIG. 7A.

Referring to FIG. 7A, the preliminary display panel DP-I according to one or more embodiments may include the base substrate BS, the circuit element layer CL, and a plurality of light-emitting element layers EDL. FIG. 7A illustrates the base substrate BS and the circuit element layer CL overlapping each other. Further, the preliminary display panel DP-I may include the plurality of display areas DA and the non-display area NDA surrounding the plurality of display areas DA, and the plurality of display areas DA may correspond to areas in which the plurality of light-emitting element layers EDL are arranged.

FIG. 7A illustrates, by way of example, that nine display areas DA are arranged, but the number of display areas DA is not limited thereto. FIG. 7A illustrates the display area DA having a quadrangular shape on a plane, but a shape thereof on a plane is not limited thereto.

FIG. 7B illustrates a cross section of the preliminary display panel DP-I including the base substrate BS, the circuit element layer CL located on the base substrate BS, and the plurality of light-emitting element layers EDL arranged on the circuit element layer CL.

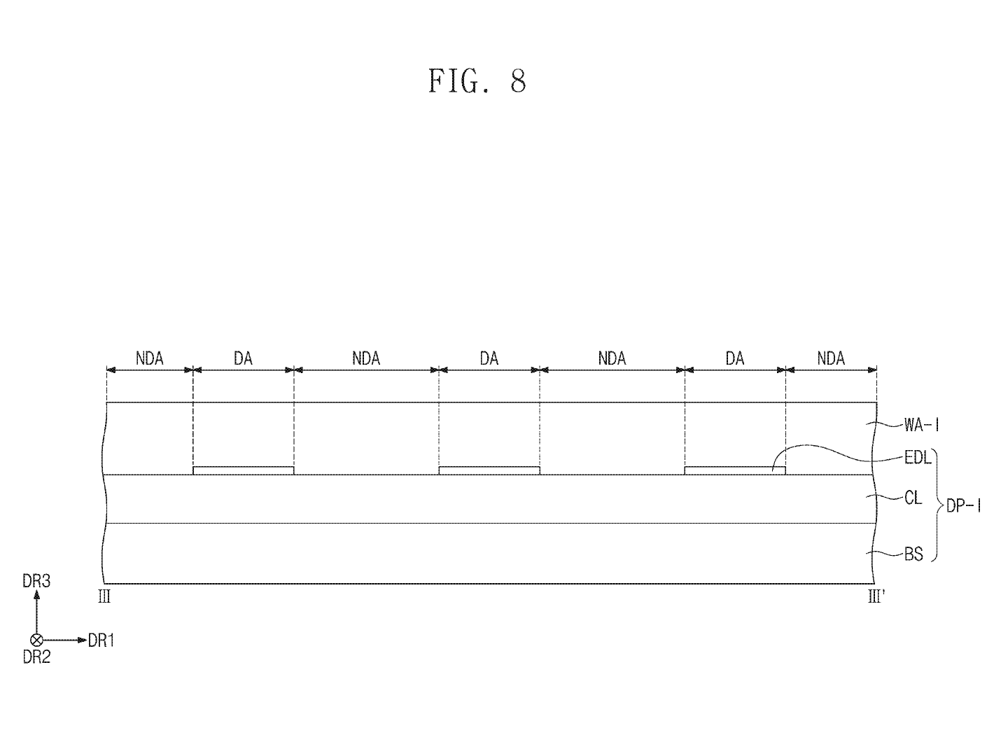

FIGS. 8-12B illustrate an operation of forming a plurality of partition walls WA on the preliminary display panel DP-I. The plurality of partition walls WA may be formed in an imprint method. For example, the operation of forming the plurality of partition walls WA may include an operation of applying a resin (e.g., a photocurable resin) WA-I, an operation of compressing a mold MOLD on the resin WA-I, an operation of curing the resin WA-I, and an operation of removing the mold MOLD.

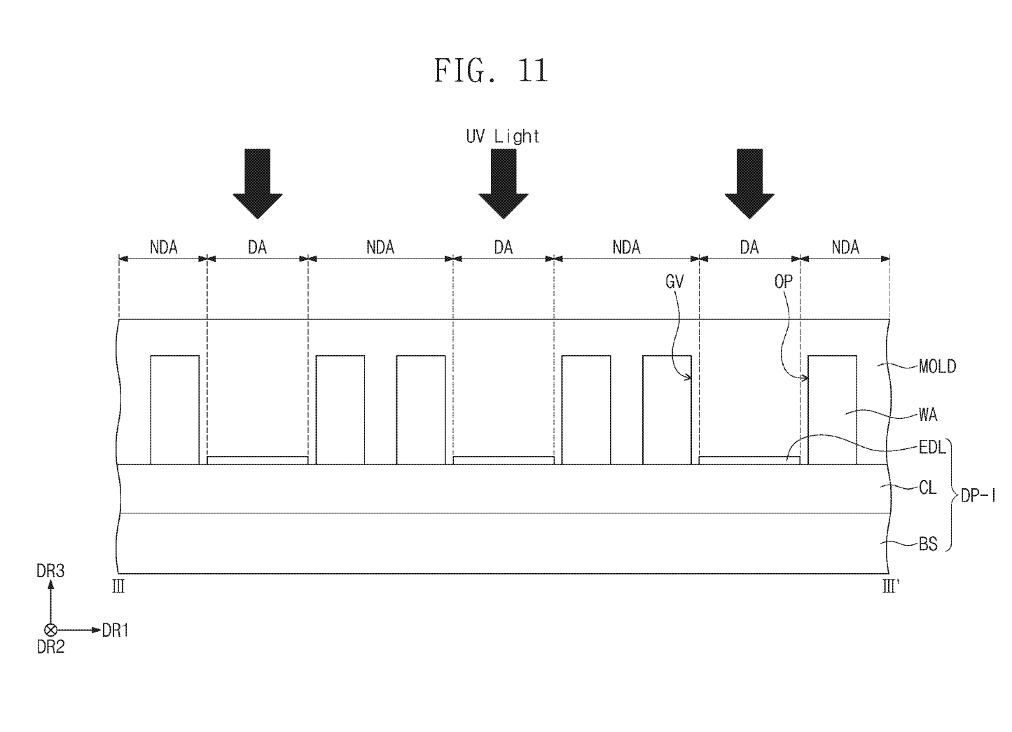

Referring to FIG. 8, the operation of forming the plurality of partition walls WA (see FIG. 11) may include an operation of applying the resin WA-I onto the preliminary display panel DP-I. The resin WA-I may be applied onto the preliminary display panel DP-I to cover the plurality of light-emitting element layers EDL. The resin WA-I may be a photocurable resin, and may have fluidity, and thus have a shape that may be deformed by a physical force.

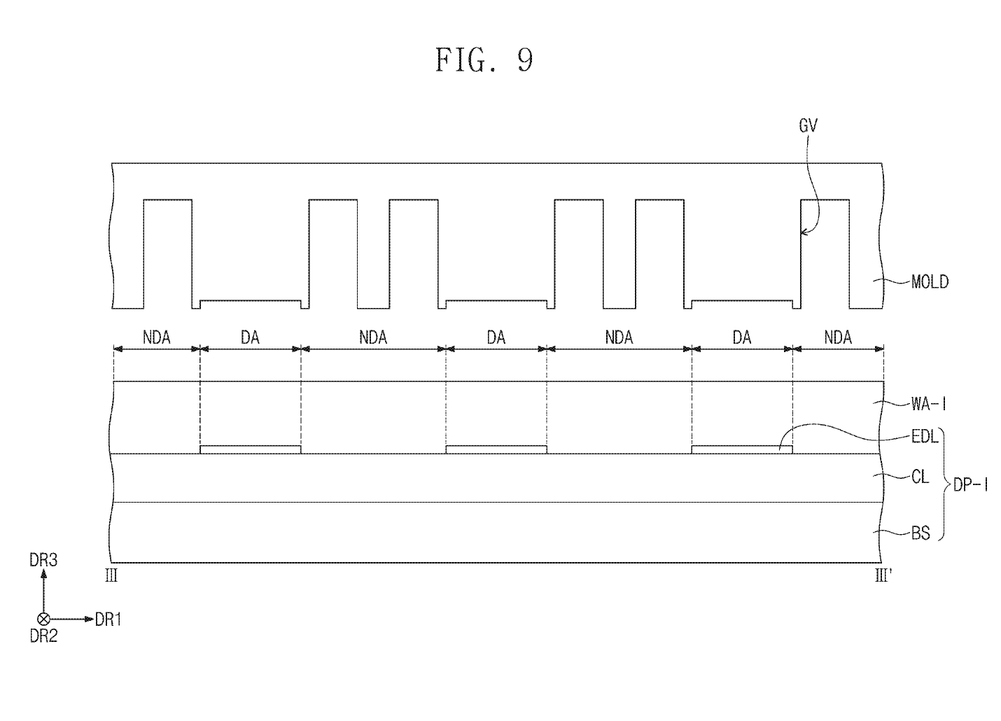

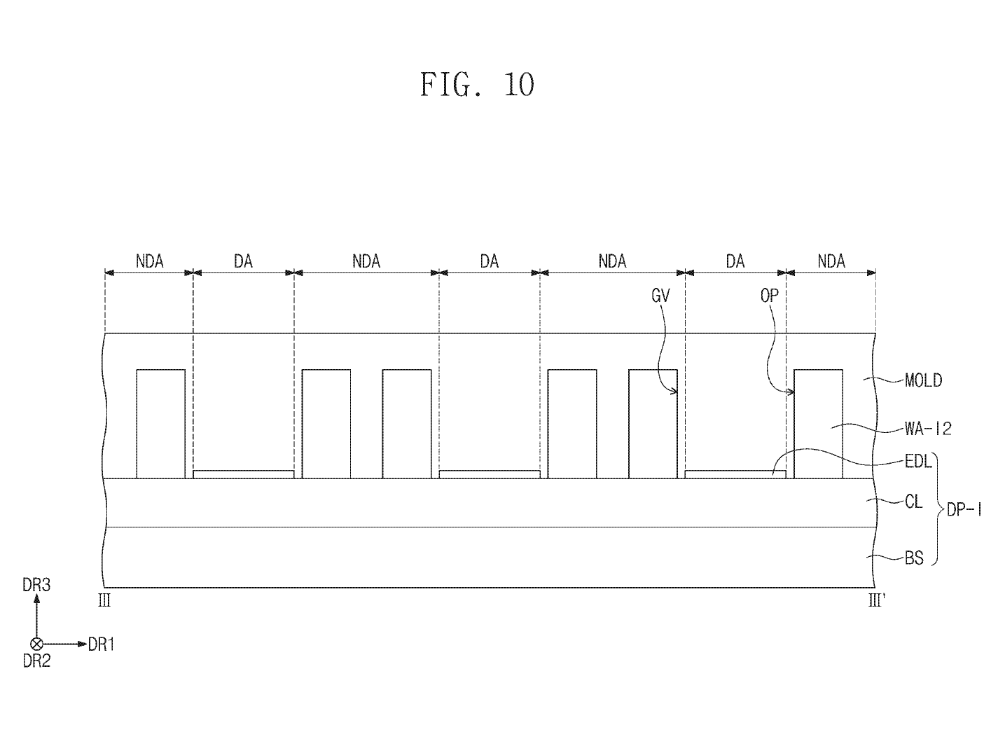

Referring to FIGS. 9 and 10, the operation of forming the plurality of partition walls WA (see FIG. 11) may include an operation of compressing the mold MOLD onto the resin WA-I. The mold MOLD may include a plurality of grooves GV. The plurality of grooves GV of the mold MOLD may have a pattern shape. For example, each of the plurality of grooves GV of the mold MOLD may have a pattern shape corresponding to a shape of the partition wall WA (see FIG. 11) to be formed. By compressing the mold MOLD onto the resin WA-I, the resin WA-I may be deformed into a shape corresponding to the pattern shapes of the plurality of grooves GV according to a pressure applied by the mold MOLD as illustrated in FIG. 10, and thus a compressed resin WA-I2 may include a pattern shape corresponding to the pattern shapes of the grooves GV. Accordingly, a thickness of the compressed resin WA-I2 may be greater than a thickness at which the resin WA-I is applied before the compression. In this case, the thickness may be defined as a length measured in the third direction DR3.

Referring to FIG. 11, the operation of forming the plurality of partition walls WA may include an operation of curing the compressed resin WA-I2 (see FIG. 10). The compressed resin WA-I2 (see FIG. 10) may be a photocurable resin and may be photocured by UV light radiation. In this case, ultraviolet rays (UV light) may be radiated to the compressed resin WA-I2 (see FIG. 10) while passing through the mold MOLD. The compressed resin WA-I2 (see FIG. 10) may be cured to form the plurality of partition walls WA. However, this is by way of example, and the compressed resin WA-I2 (see FIG. 10) may be cured in various manners to form the plurality of partition walls WA. For example, the compressed resin WA-I2 (see FIG. 10) may be a thermosetting resin and may be cured by heat treatment.

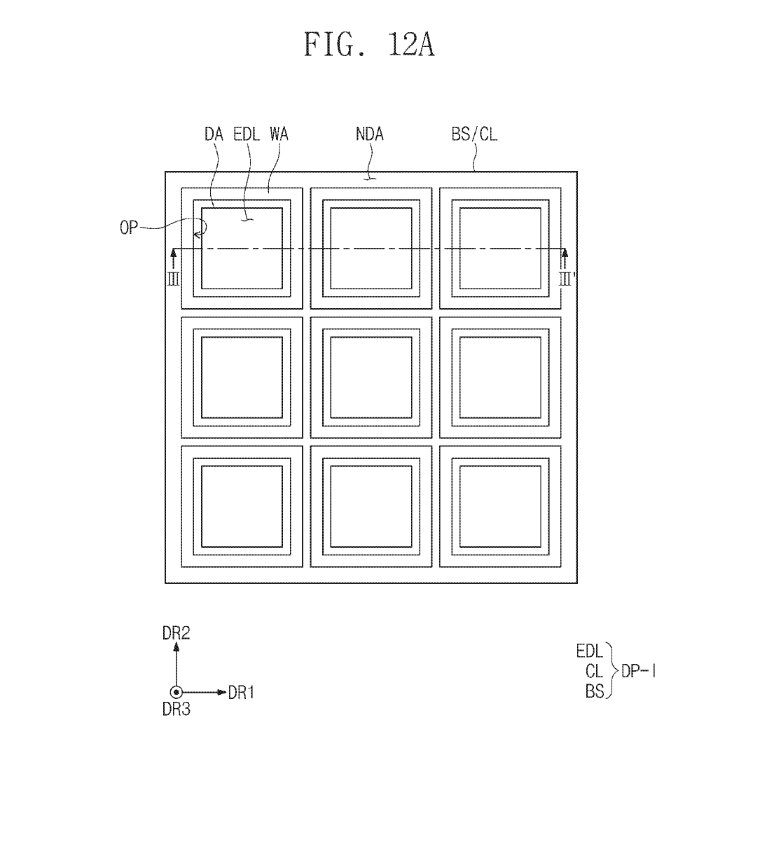

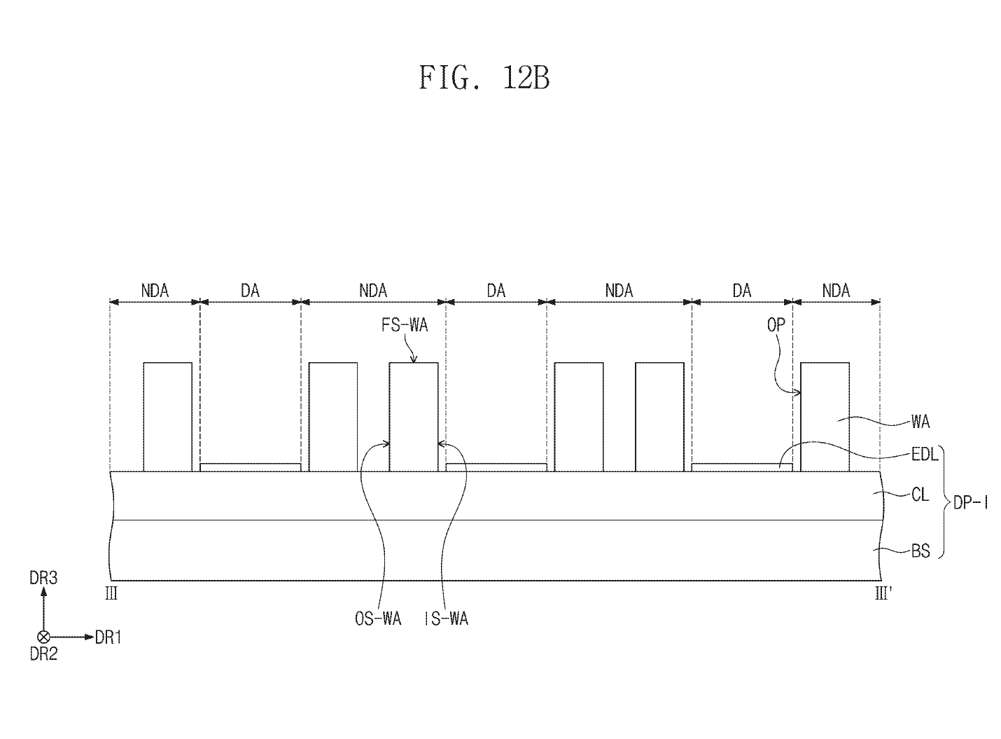

Referring to FIGS. 12A and 12B, the operation of forming the plurality of partition walls WA may include an operation of removing the mold MOLD. Because the mold MOLD is removed, the plurality of partition walls WA may be formed on the circuit element layer CL. Accordingly, the plurality of partition walls WA surrounding the plurality of display areas DA may be concurrently or substantially simultaneously formed. FIG. 12A is a plan view in which the plurality of partition walls WA are formed on the preliminary display panel DP-I by removing the mold MOLD. FIG. 12B is a cross-sectional view along the line III-III' of FIG. 12A.

Referring to FIG. 12A, when the mold MOLD is removed, the plurality of partition walls WA respectively surrounding the plurality of display areas DA may be formed. The plurality of partition walls WA may be formed in the non-display area NDA as illustrated in FIG. 12A. Openings OP of the plurality of partition walls WA may surround the plurality of display areas DA, respectively. FIG. 12A illustrates, by way of example, that planar shapes of the plurality of partition walls WA and the openings OP are quadrangular, but this is by way of example, and the planar shapes of the partition walls WA and the openings OP may have one or more embodiments as long as the plurality of partition walls WA surround the display areas DA, respectively.

Referring to FIG. 12B, the plurality of partition walls WA may be spaced apart from the plurality of light-emitting element layers EDL. Alternatively, unlike FIG. 12B, the plurality of partition walls WA may contact the plurality of light-emitting element layers EDL. Further, the plurality of partition walls WA may be directly formed on the circuit element layer CL.

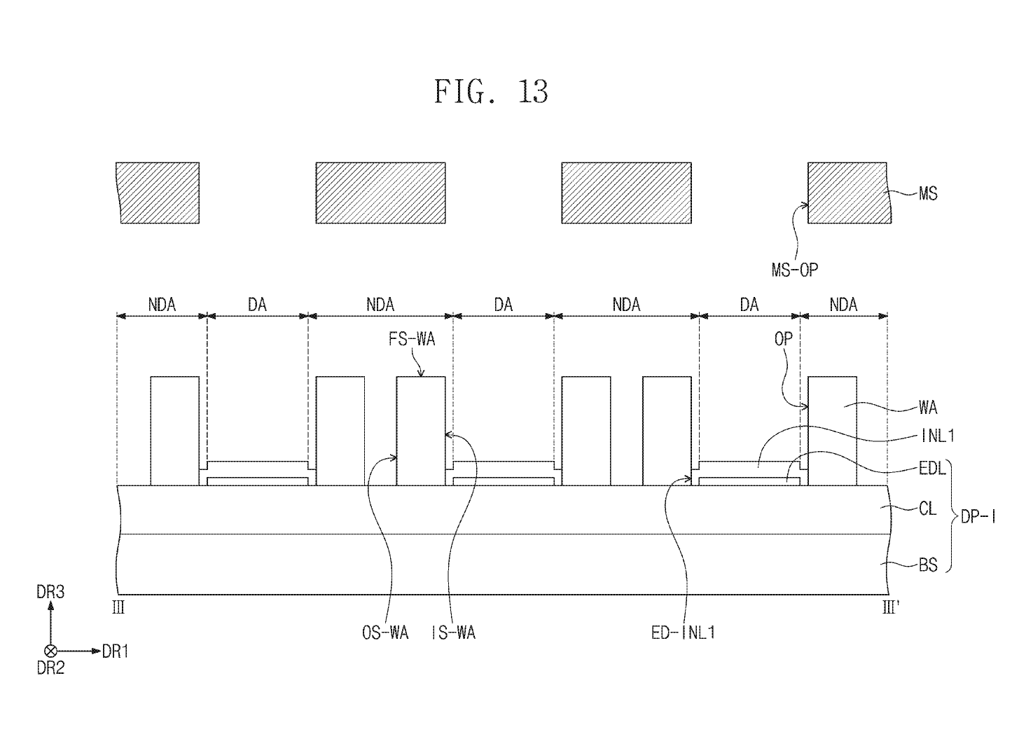

FIGS. 13-15B illustrate an operation of forming the plurality of encapsulation layers TFE. The operation of forming the plurality of encapsulation layers TFE may include an operation of forming the plurality of first inorganic layers INL1, an operation of forming the plurality of organic layers OL, and an operation of forming the plurality of second inorganic layers INL2.

Referring to FIG. 13, the operation of forming the plurality of encapsulation layers TFE may include the operation of forming the plurality of first inorganic layers INL1. The plurality of first inorganic layers INL1 may be formed on the plurality of light-emitting element layers EDL, respectively. The plurality of first inorganic layers INL1 may be formed inside the plurality of openings OP, respectively. The plurality of first inorganic layers INL1 may be deposited by a chemical vapor deposition (CVD) method. For example, the plurality of first inorganic layers INL1 may be formed by depositing an inorganic material inside the openings OP through a mask MS including mask openings MS-OP corresponding to the openings OP of the plurality of partition walls WA. Alternatively, after an inorganic material is deposited on the preliminary display panel DP-I as a whole, some of the plurality of first inorganic layers INL1 formed in the non-display area NDA may be removed through an ashing process or the like, and thus the plurality of first inorganic layers INL1 may be formed inside the plurality of openings OP, respectively.

As the plurality of first inorganic layers INL1 are formed inside the plurality of openings OP, respectively, the first edge ED-INL1 in contact with the inner side surface IS-WA of the partition wall WA may be formed in the plurality of first inorganic layers INL1. When the inner side surface IS-WA of the partition wall WA is perpendicular to the plane parallel to the base substrate BS, the first edge ED-INL1 may be perpendicular to the plane parallel to the base substrate BS.

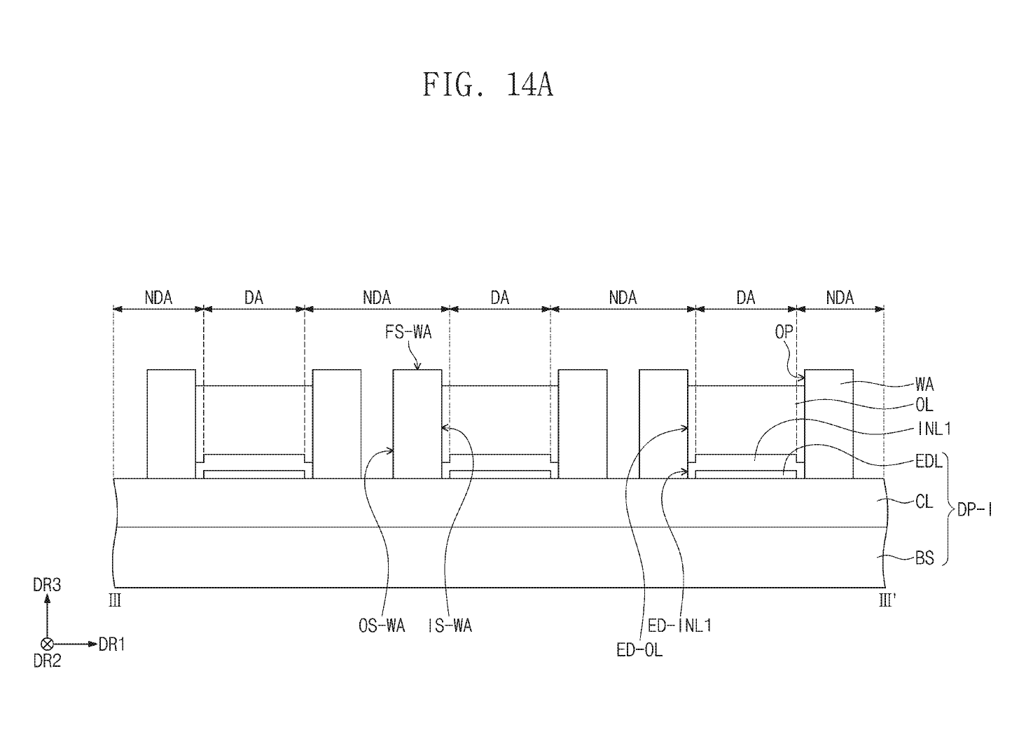

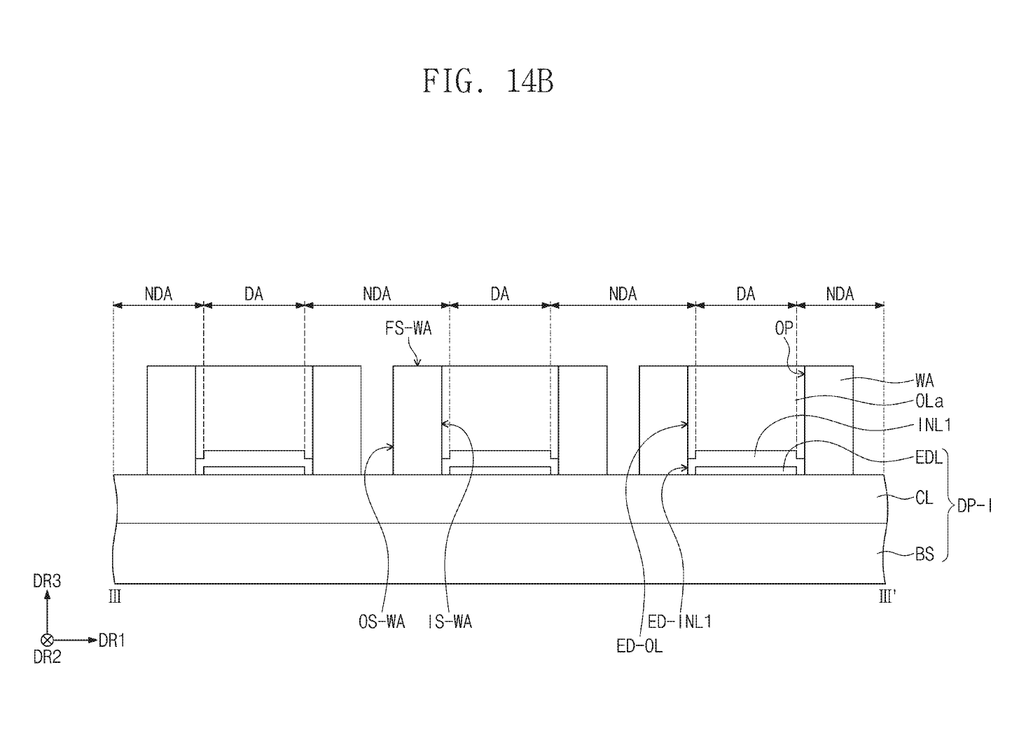

Referring to FIG. 14A, the operation of forming the plurality of encapsulation layers TFE may include the operation of forming the plurality of organic layers OL. The plurality of organic layers OL may be formed on the plurality of first inorganic layers INL1. According to one or more embodiments of the present disclosure, the plurality of organic layers OL may be formed by applying a fluidic organic material into the plurality of openings OP. Accordingly, the organic material may be blocked by the partition wall WA, and thus, reflow may not occur. The organic material may be applied and then cured to form the plurality of organic layers OL. The organic material may be photocured by being irradiated with ultraviolet rays (UV light).

The second edge ED-OL in contact with the inner side surface IS-WA of the partition wall WA may be formed in the plurality of organic layers OL. When the inner side surface IS-WA of the partition wall WA is perpendicular to the plane parallel to the base substrate BS, the second edge ED-OL may be perpendicular to the plane parallel to the base substrate BS. The second edge ED-OL may be aligned with the first edge ED-INL1.

FIG. 14B illustrates, by way of example, an operation of forming the plurality of organic layers OLa according to one or more embodiments of the present disclosure. In detail, FIG. 14B illustrates an operation of manufacturing the display panel DPa (see FIG. 6) illustrated in FIG. 6. Referring to FIG. 14B, the plurality of organic layers OLa may completely fill insides of the openings OP of the plurality of partition walls WA, respectively, unlike FIG. 14A. That is, the organic layer OLa may be formed up to a height of the upper surface FS-WA of the partition wall WA. Accordingly, the plurality of organic layers OLa may provide flat surfaces to the plurality of second inorganic layers INL2a and thus help deposition of the plurality of second inorganic layers INL2a.

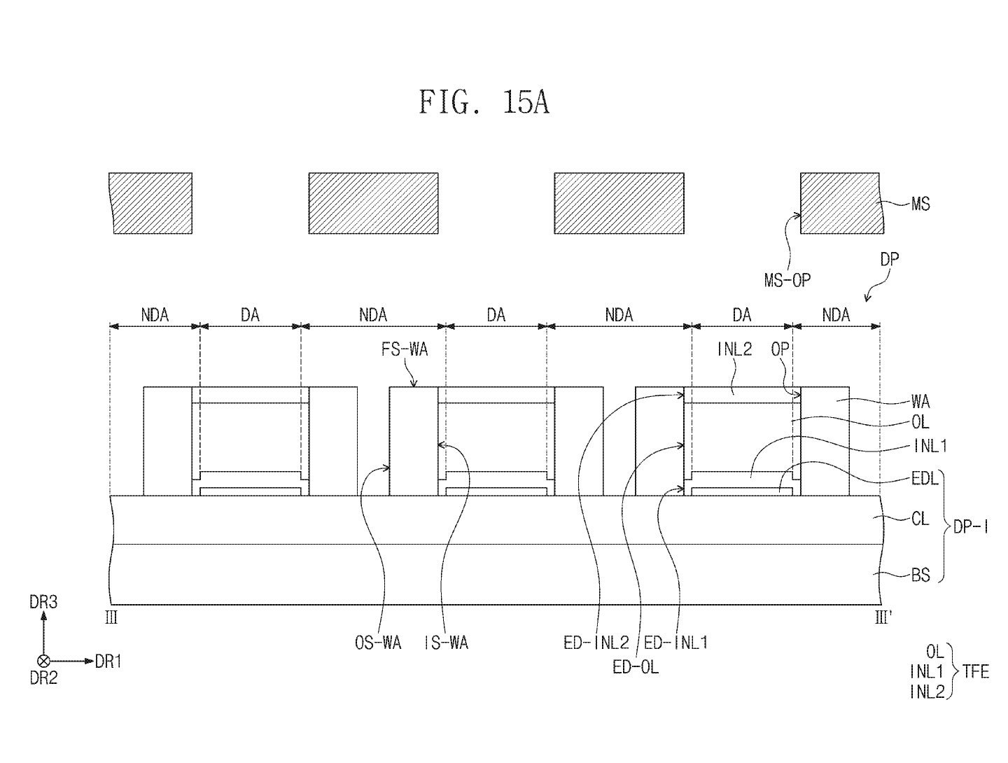

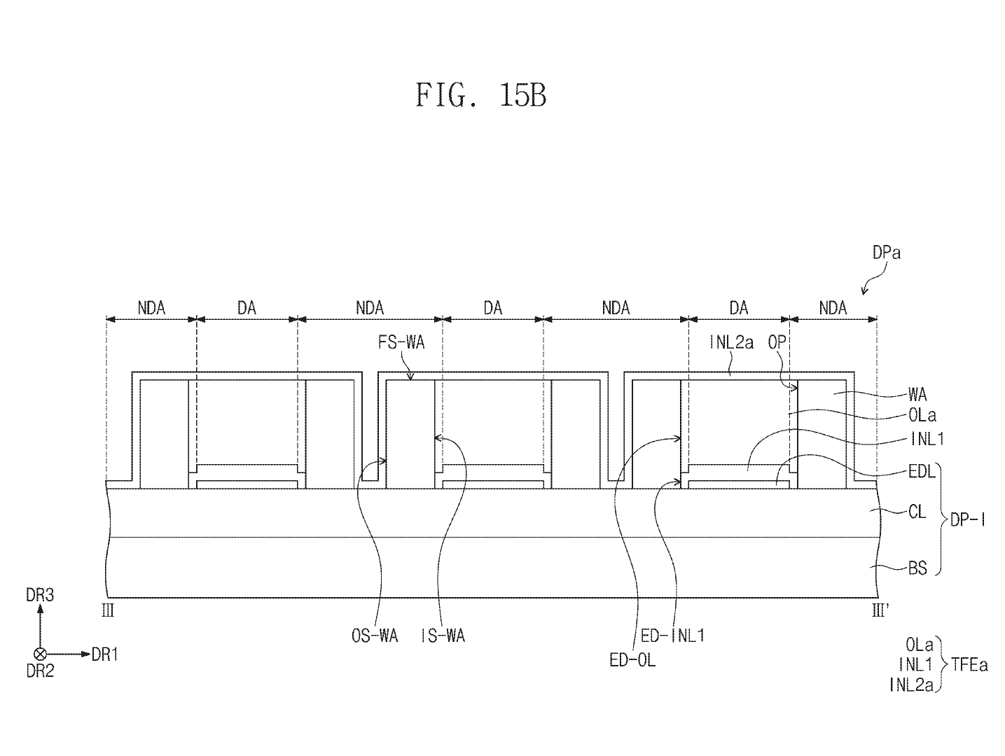

Referring to FIG. 15A, the operation of forming the plurality of encapsulation layers TFE may include the operation of forming the plurality of second inorganic layers INL2. The plurality of second inorganic layers INL2 may be formed on the plurality of organic layers OL, respectively. The plurality of second inorganic layers INL2 may be deposited by a CVD method to cover the plurality of organic layers OL.

The plurality of second inorganic layers INL2 may be formed inside the openings OP of the plurality of partition walls WA, respectively. For example, the plurality of second inorganic layers INL2 may be formed by depositing an inorganic material inside the openings OP of the plurality of partition walls WA through the mask MS including the mask openings MS-OP corresponding to the openings OP of the plurality of partition walls WA. Alternatively, after an inorganic material is deposited on the preliminary display panel DP-I as a whole, some of the plurality of second inorganic layers INL2 formed in the non-display area NDA may be removed through an ashing process or the like, and thus the plurality of second inorganic layers INL2 may be formed inside the plurality of openings OP, respectively. In this way, as the plurality of second inorganic layers INL2 are formed inside the openings OP of the plurality of partition walls WA, the third edge ED-INL2 in contact with the inner side surface IS-WA of the partition wall WA may be formed in the plurality of second inorganic layers INL2. When the inner side surface IS-WA of the partition wall WA is perpendicular to the plane parallel to the base substrate BS, the third edge ED-INL2 may be perpendicular to the plane parallel to the base substrate BS. The third edge ED-INL2 may be aligned with the first edge ED-INL1 and the second edge ED-OL.

FIG. 15B illustrates, by way of example, that the second inorganic layer INL2a is formed according to one or more embodiments of the present disclosure. In detail, FIG. 15B illustrates an operation of manufacturing the display panel DPa illustrated in FIG. 6. Referring to FIG. 15B, the plurality of second inorganic layers INL2a may be deposited to cover at least portions of the organic layer OLa and the partition wall WA. For example, the second inorganic layer INL2a may be deposited to cover the partition wall WA and the organic layer OLa illustrated in FIG. 14B. Accordingly, the second inorganic layer INL2a may cover the upper surface FS-WA and the outer side surface OS-WA of the partition wall WA. The second inorganic layer INL2a may be formed as one common layer on the preliminary display panel DP-I. Accordingly, as illustrated in FIG. 15B, the second inorganic layer INL2a may be deposited to have an integral shape by being connected onto the plurality of light-emitting element layers EDL. That is, the plurality of second inorganic layers INL2 illustrated in FIG. 15A may be deposited to have an integral shape through the connection. However, the shapes of the second inorganic layers INL2 and INL2a illustrated in FIGS. 15A and 15B are by way of example, and one or more embodiments may be provided as long as the second inorganic layers INL2 and INL2a may cover the organic layers OL and OLa.

In one or more embodiments, the method may further include an operation of cutting the preliminary display panel DP-I after the plurality of partition walls WA and the plurality of encapsulation layers TFE are formed, and providing the preliminary display panel DP-I as the plurality of display panels DP (see FIGS. 5A- 6). Accordingly, the plurality of display panels DP (see FIGS. 5A-6) may be provided to the display panels DP (see FIGS. 5A-6) of the electronic device ED (see FIGS. 1-4).

According to the present disclosure, the encapsulation layers TFE including the plurality of first inorganic layers INL1, the plurality of organic layers OL, and the plurality of second inorganic layers INL2 may be concurrently or substantially simultaneously formed on the plurality of light-emitting element layers EDL. Accordingly, compared to a case in which the plurality of organic layers OL are respectively formed on the plurality of light-emitting element layers EDL through an inkjet process, according to the present disclosure, the plurality of organic layers OL may be concurrently or substantially simultaneously formed on the plurality of light-emitting element layers EDL, and thus a tact time may be reduced and process efficiency may be improved.

In a display panel and an electronic device according to the present disclosure, a partition wall may be included to reduce an area of a non-display area.

In a method of manufacturing a display panel according to the present disclosure, a partition wall may be included to improve process efficiency.

Although the description has been made above with reference to one or more embodiments of the present disclosure, it may be understood that those skilled in the art or those having ordinary knowledge in the art may variously modify and change the present disclosure without departing from the spirit and technical scope of the present disclosure described in the appended claims.

Thus, the technical scope of the present disclosure is not limited to the detailed description of the specification but should be defined by the appended claims, with functional equivalents thereof to be included therein.

What is claimed is:

1. A display panel comprising:
a base substrate comprising:
a display area; and
a non-display area surrounding the display area in plan view, and comprising a first non-display area, and a second non-display area surrounding the first non-display area in plan view;
a circuit element layer above the base substrate;
a light-emitting element layer comprising a light-emitting element in the display area and above the circuit element layer;
a partition wall defining an opening surrounding the display area in plan view, overlapping the first non-display area, and above the circuit element layer; and
an encapsulation layer above the light-emitting element layer and comprising a first inorganic layer inside the opening and not overlapping the second non-display area, an organic layer above the first inorganic layer, inside the opening, and not overlapping the second non-display area, and a second inorganic layer above the organic layer.

2. The display panel of claim 1, wherein the partition wall comprises an inner side surface corresponding to the opening, and an outer side surface opposite to the inner side surface, and
wherein the inner side surface and the outer side surface are substantially perpendicular to the base substrate.

3. The display panel of claim 2, wherein the second inorganic layer is inside the opening and does not overlap the second non-display area.

4. The display panel of claim 3, wherein a thickness of the partition wall is equal to or greater than a thickness of the encapsulation layer.

5. The display panel of claim 3, wherein the first inorganic layer comprises a first edge contacting the inner side surface of the partition wall,
wherein the organic layer comprises a second edge contacting the inner side surface of the partition wall,
wherein the second inorganic layer comprises a third edge contacting the inner side surface of the partition wall, and
wherein the first edge, the second edge, and the third edge are aligned.

6. The display panel of claim 5, wherein the first edge, the second edge, and the third edge are substantially perpendicular to the base substrate.

7. The display panel of claim 1, wherein the partition wall is directly on the circuit element layer.

8. The display panel of claim 1, wherein the partition wall comprises an upper surface spaced from the circuit element layer and substantially parallel to the base substrate.

9. The display panel of claim 1, wherein the partition wall is spaced from the light-emitting element layer in plan view.

10. The display panel of claim 1, wherein the partition wall comprises a photocurable resin.

11. An electronic device comprising:
a window comprising a transmissive area, and a bezel area surrounding the transmissive area; and
a display panel below the window, and comprising:
a base substrate comprising:
a display area; and
a non-display area surrounding the display area in plan view and comprising a first non-display area and a second non-display area surrounding the first non-display area in plan view;
a circuit element layer above the base substrate;
a light-emitting element layer comprising a light-emitting element in the display area and above the circuit element layer;
a partition wall defining an opening surrounding the display area, overlapping the first non-display area, and above the circuit element layer; and
an encapsulation layer above the light-emitting element layer and comprising a first inorganic layer inside the opening and not overlapping the second non-display area, an organic layer above the first inorganic layer, inside the opening, and not overlapping the second non-display area, and a second inorganic layer above the organic layer.

12. The electronic device of claim 11, further comprising at least one of a processor, a memory, or a power module.

13. The electronic device of claim 11, wherein the electronic device is a television, a monitor, an external billboard, a personal computer, a laptop computer, a personal digital terminal, a car instrument panel, a center fascia, a navigation system, a room mirror display, a game console, a smartphone, a tablet computer, a smart watch, smart glasses, a head-mounted display, or a camera.

14. A method of manufacturing a display panel, the method comprising:
providing a preliminary display panel comprising a base substrate, a circuit element layer above the base substrate, and light-emitting element layers above the circuit element layer;
forming partition walls surrounding the light-emitting element layers in plan view and defining openings overlapping the light-emitting element layers above the preliminary display panel using a mold; and
forming encapsulation layers above the light-emitting element layers by:
forming first inorganic layers inside the openings above the light-emitting element layers; and
forming organic layers inside the openings above the first inorganic layers.

15. The method of claim 14, wherein the forming of the partition walls comprises:
applying a photocurable resin onto the preliminary display panel;
compressing the mold onto the photocurable resin;
photocuring the photocurable resin by radiating an ultraviolet ray to the photocurable resin; and
removing the mold.

16. The method of claim 14, wherein the forming of the first inorganic layers comprises depositing an inorganic material inside the openings using a mask defining mask openings corresponding to the openings.

17. The method of claim 14, wherein the forming of the encapsulation layers further comprises forming second inorganic layers inside the openings above the organic layers.

18. The method of claim 17, wherein the forming of the second inorganic layers comprises depositing an inorganic material inside the openings using a mask defining mask openings corresponding to the openings.

19. The method of claim 17, wherein the partition walls comprise inner side surfaces corresponding to the openings and outer side surfaces opposite to the inner side surfaces,
wherein the first inorganic layers comprise first edges respectively contacting the inner side surfaces,
wherein the organic layers comprise second edges respectively contacting the inner side surfaces,
wherein the second inorganic layers comprise third edges respectively contacting the inner side surfaces, and
wherein the first edge, the second edge, and the third edge are aligned.

20. The method of claim 14, further comprising forming display panels by cutting the preliminary display panel in which the partition walls and the encapsulation layers are formed.
